(19) United States
(12) Patent Application Publication
(10) Pub. No.: US 2026/0206541 A1
(43) Pub. Date: Jul. 16, 2026

(54) COMPUTATIONALLY GUIDED DESIGN AND FABRICATION OF SPIN-DEFECT SYSTEMS FOR QUANTUM TECHNOLOGIES

(71) Applicants: The University of Chicago, Chicago, IL (US); UCHICAGO ARGONNE, LLC, Chicago, IL (US)

(72) Inventors: David AWSCHALOM, Chicago, IL (US); Jonathan C. MARCKS, Chicago, IL (US); Mykyta ONIZHUK, Chicago, IL (US); Yuxin WANG, Chicago, IL (US); Masaya FUKAMI, Chicago, IL (US); Nazar DELEGAN, Chicago, IL (US); Joseph HEREMANS, Chicago, IL (US); Aashish CLERK, Chicago, IL (US); Giulia GALLI, Chicago, IL (US)

(21) Appl. No.: 19/132,468

(22) PCT Filed: Nov. 17, 2023
(86) PCT No.: PCT/US2023/080236

§ 371 Date: May 23, 2025

Related U.S. Application Data
(60) Provisional application No. 63/384,851, filed on Nov. 23, 2022.
(60) Provisional application No. 63/458,996, filed on Apr. 13, 2023.

(51) Int. Cl. H10P 74/20; G01R 33/26

(52) U.S. Cl. CPC H10P 74/20; G01R 33/26

(57) ABSTRACT

A coherence model predicts the coherence time of one spin qubit based on decoherence caused by a surrounding spin bath. This coherence model, which is constructed by performing cluster correlation expansion calculations of spin-bath-induced decoherence, includes a library of coherence time distributions over a parameter-space range. Using this library, maximum likelihood estimation is then performed on a set of experimental data, enabling the density of the spin bath and the dimensionality of the spin qubits to be determined, given certain geometrical constraints. Rather than relying on assumptions that average over interactions between bath spins and central qubit spins, the present embodiments simulate the dynamics of the entire interacting spin bath, producing a quantum mechanical characterization technique for quantum applications that can be incorporated into a feedforward synthesis loop.

### RELATED APPLICATIONS

This application claims priority to U.S. Provisional Patent Application No. 63/384,851, filed on Nov. 23, 2022, and U.S. Provisional Patent Application No. 63/458,996, filed on Apr. 13, 2023. Each of these applications is incorporated herein by reference in its entirety.

### STATEMENT REGARDING FEDERALLY SPONSORED RESEARCH OR DEVELOPMENT

This invention was made with government support under grant number FA9550-19-1-0358, awarded by the Air Force Office of Scientific Research, and grant number DE-AC02-06CH11357, awarded by the U.S. Department of Energy. The government has certain rights in the invention.

### BACKGROUND

The nitrogen-vacancy (NV) center in diamond is a well-studied, optically active spin defect that is the prototypical system in many state-of-the-art quantum sensing and communication applications. In addition to the properties intrinsic to the NV center, the nuclear and electronic spin baths of the diamond host material can be leveraged as resources for quantum information, rather than considered solely as sources of decoherence.

### SUMMARY

Quantum sensors based on electron spin qubits hold promise for a variety of applications ranging from the life sciences to fundamental materials physics. A roadblock to deterministic and scalable production of single qubits is proper characterization of substrates and in-situ defect growth. The densities, dimensionalities, and localization required for highly coherent qubits are difficult to harmonize with the current limits of characterization techniques, necessitating a new technique that relies on the quantum dynamics of the system.

To solve these problems, the present embodiments use a coherence model created by cluster correlation expansion (CCE) calculations of spin-bath-induced decoherence to generate a library of coherence time distributions over a parameter-space range. A maximum likelihood estimation is then performed on a set of experimental data with this library, enabling one to extract the density and dimensionality of spin defects incorporated in a host lattice given certain geometrical constraints. Rather than relying on assumptions that average over interactions between bath spins and central spins, the present embodiments simulate the dynamics of the entire interacting spin bath, producing a quantum mechanical characterization technique for quantum applications that can be incorporated into a feedforward synthesis loop. Due to this feedforward, the present embodiments will aid in production of quantum sensors at the foundry level in arbitrary host materials.

We experimentally demonstrate the present embodiments with nitrogen-vacancy (NV) center electron spin qubits in diamond. As part of this demonstration, a coherence model was constructed to simulate the behavior of one NV qubit surrounded by a spin bath of P1 centers (i.e., substitutional nitrogen atoms

$${N}_{S}^{0}$$

with an electron spin S=½, located at random positions. The spin bath is characterized by spin-bath parameters (e.g., density of the P1 centers, spatial dimensions of the bath, etc.). The coherence model predicts the coherence time of the one NV qubit, taking into account decoherence caused by the surrounding spin bath.

A spin bath of P1 centers is one of the dominant sources of decoherence for NV qubits in diamond. However, the present embodiments may be used to model other types of defects or particles for the spin bath. For example, instead of P1 centers, the spin bath may be formed from 13C atoms, where the nuclear spins of 13C atoms couple to an NV qubit via hyperfine coupling, thereby limiting the dephasing time

$${T}_{2}^{*}$$

of the NV qubit. In other example, the spin bath is formed from other NV centers (negatively charged, neutrally charged, positively charged, or a combination thereof) that couple to the one NV qubit. In another example, the spin bath is formed from electron spin-containing or nuclear spin-containing defects or lattice sites, or a combination thereof.

The present embodiments are also not limited to NV qubits in diamond. More generally, the present embodiments can be used with any other type of qubit whose coherence may be affected by a surrounding bath. Examples of such qubits include, but are not limited to, any kind of defect center (e.g., color centers) in a crystalline material (e.g., SiC, GaN, Si, GaAs, etc.), molecular qubits embedded with a host lattice, and semiconductor quantum dots. For these other types of qubit, the composition of the spin bath will depend on the material at hand.

The term “coherence time” is used herein to refer to any quantitative measure of coherence of a spin qubit. In some of the present embodiments, the coherence time is the inhomogeneous relaxation time

$${T}_{2}^{*} ,$$

which is commonly measured using Ramsey interferometry (also known as the method of separated oscillatory fields). In other embodiments, the coherence time is the homogeneous relaxation time T₂, which may be measured using dynamical decoupling (e.g., Hahn echo sequence, an XY—N pulse sequence, a Carr-Purcell-Meiboom-Gill pulse sequence, or another type of multi-pulse sequence known in the art) or double resonance spectroscopy (e.g., double electron-electron resonance spectroscopy or electron-nuclear double resonance spectroscopy). The present embodiments may be used with a different definition of “coherence time” without departing from the scope hereof.

### BRIEF DESCRIPTION OF THE FIGURES

FIG. 1 is a flow chart of a method for synthesizing NV centers, in accordance with the present embodiments.

FIG. 2A is a schematic representation of the cluster correlation expansion (CCE) approach.

FIG. 2B is an example of Hahn-echo coherence calculated for 14N P1 spin baths of various densities.

FIG. 2C is a plot of T₂ and

$${T}_{2}^{*}$$

coherence times overlaid with corresponding experimental data.

FIG. 2D is a schematic of isotopically pure (¹²C) plasma-enhanced chemical vapor deposition (PECVD) diamond overgrowth with isotopically tagged 15N nitrogen δ-doping.

FIG. 2E is a plot of carbon isotope concentration measured via secondary ion mass spectroscopy (SIMS). This plot demonstrates isotopic purification of the host material. Carbon SIMS is used to calibrate growth rate, shown in FIG. 2D.

FIG. 2F is a plot of nitrogen isotope concentration measured via SIMS. This plot demonstrates the incorporation of isotopically tagged nitrogen.

FIG. 3A illustrates Ramsey (left) and Hahn echo (right) microwave measurement pulse sequences.

FIGS. 3B and 3C are plots of the mean μ and variance σ², respectively, of coherence-time distributions of

$${T}_{2}^{*}$$

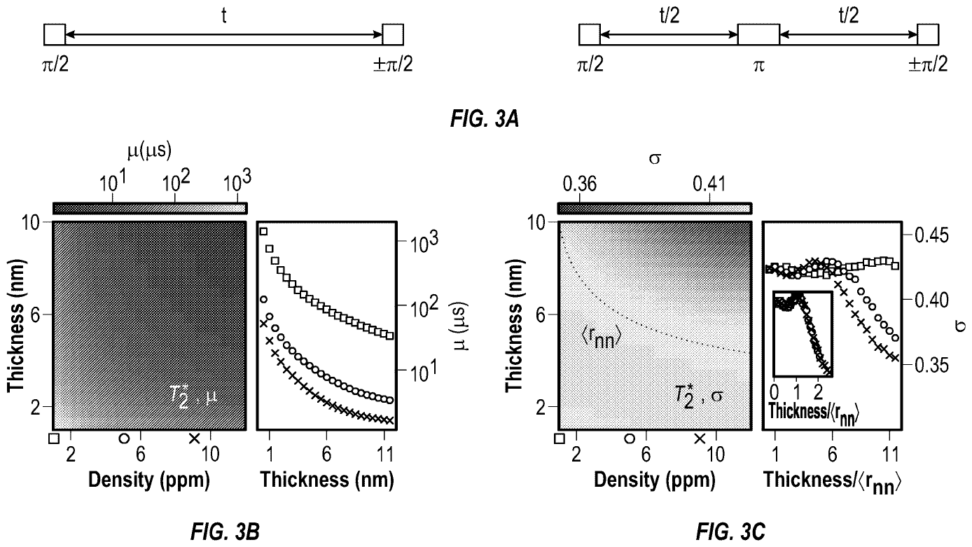

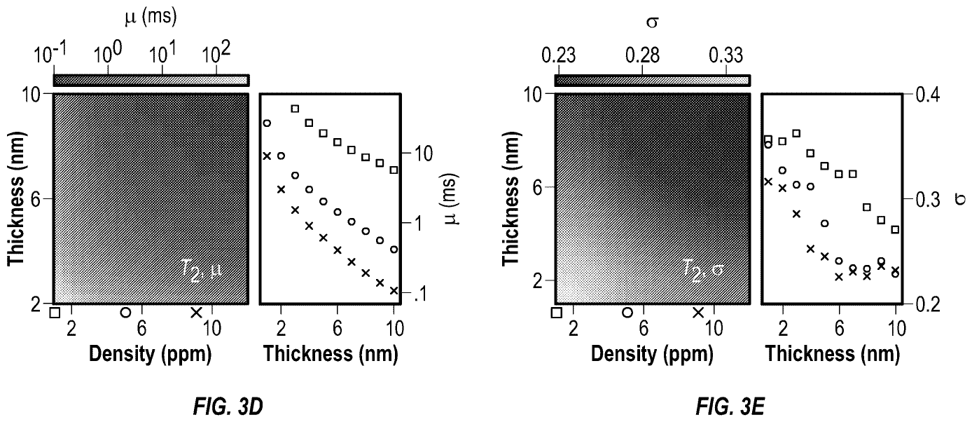

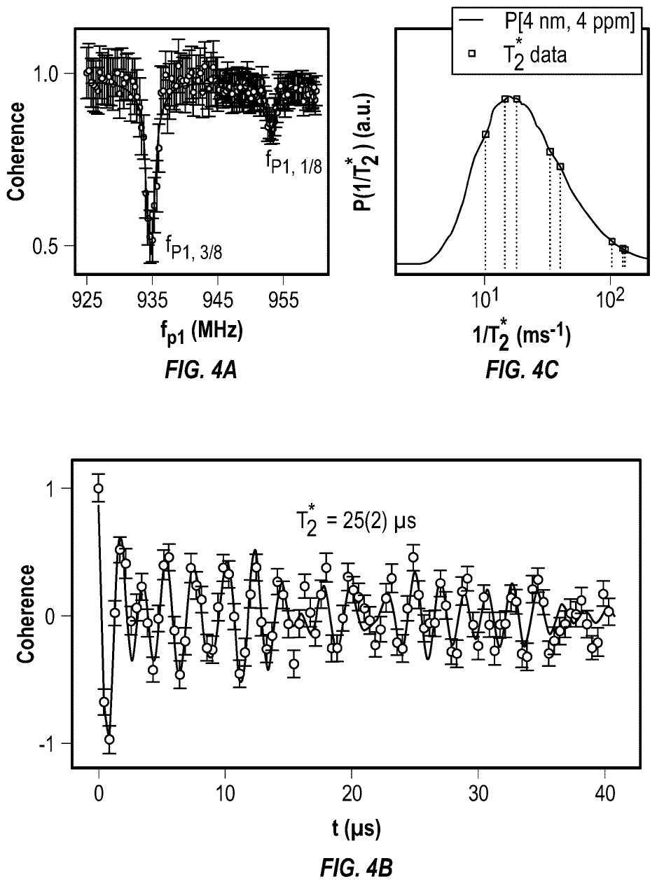

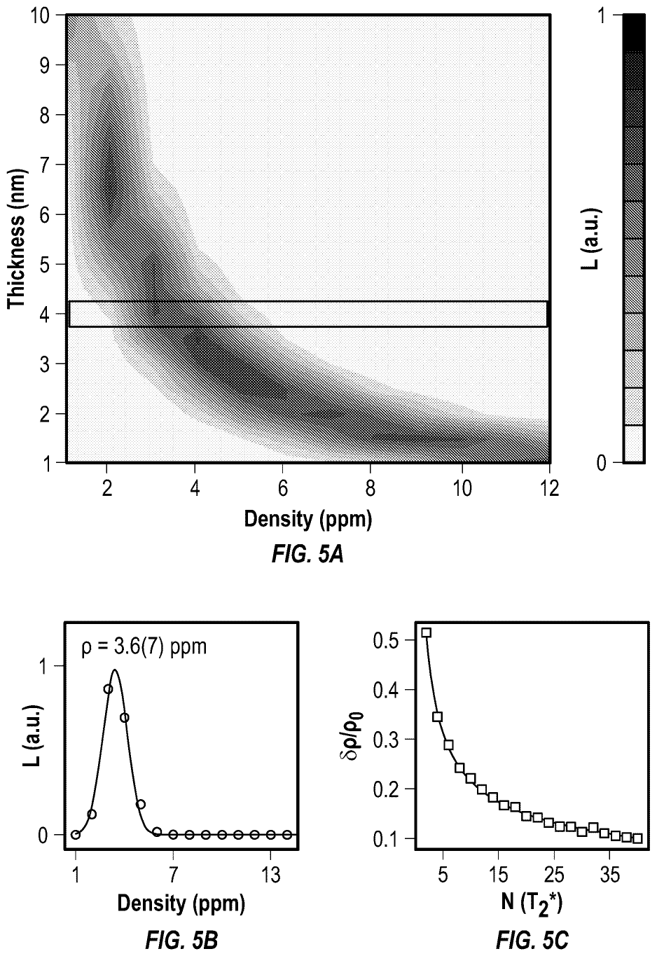

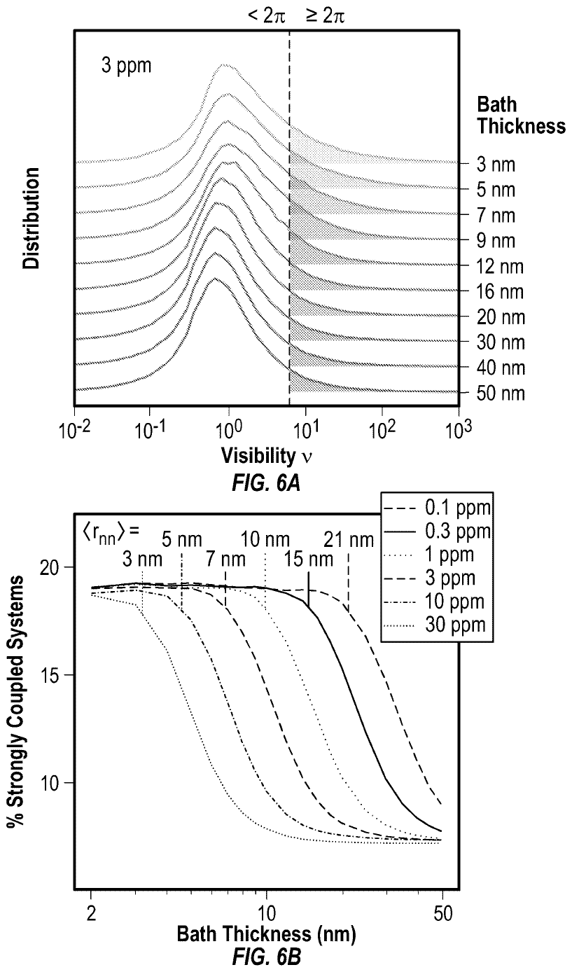

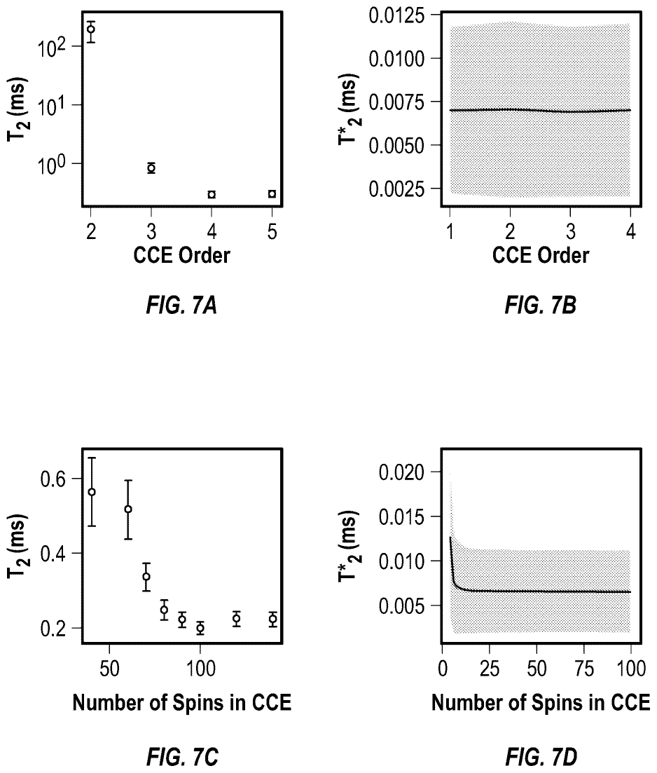

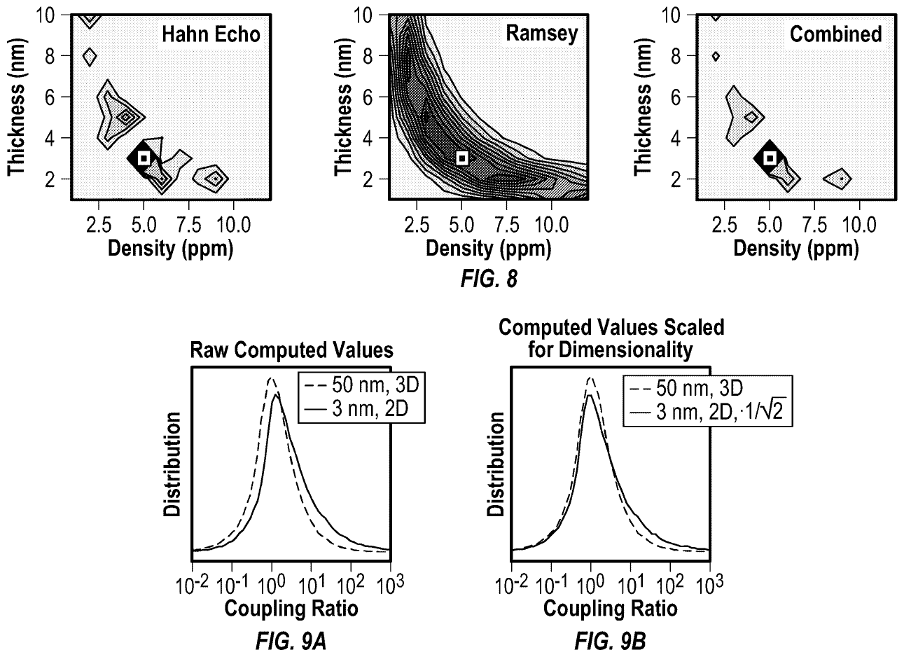

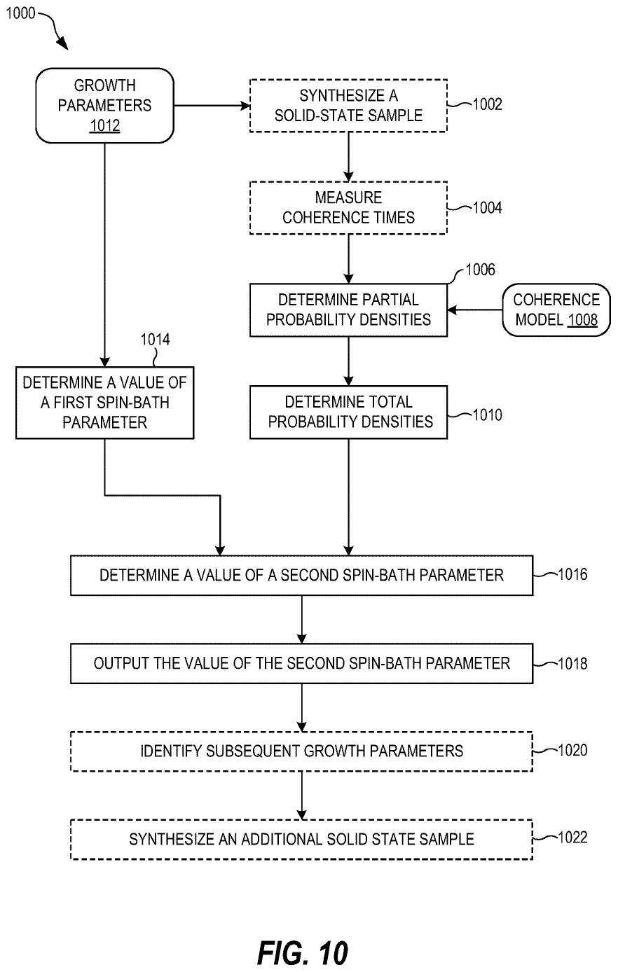

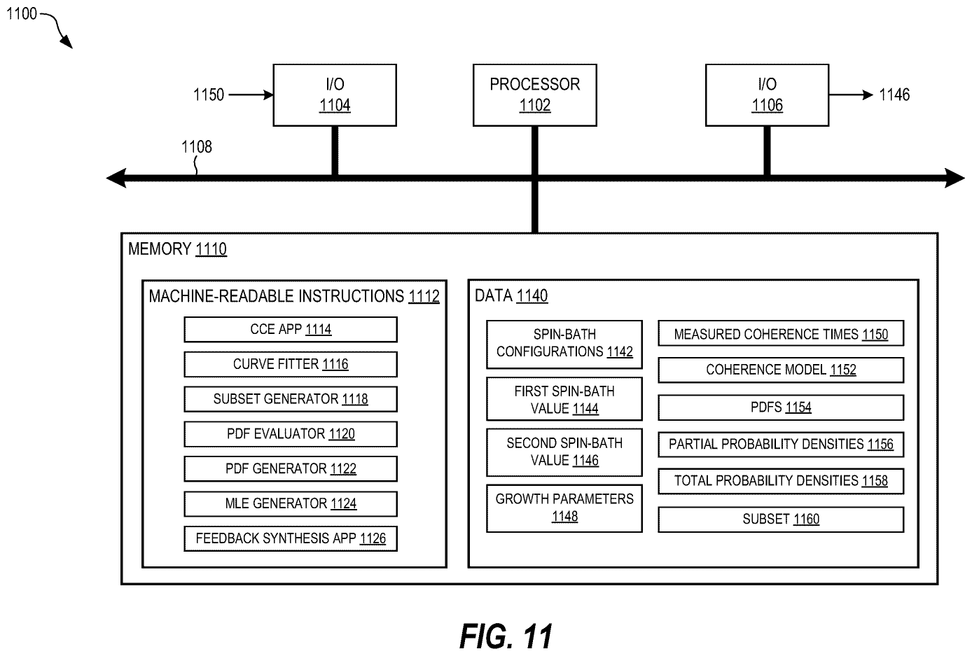

a function of P1 density anu layer thickness. Values are linearly interpolated between datapoints. The dashed line in FIG. 3C indicates the thickness equal to the average nearest-neighbor bath spin distance [symbol] rₙₙ [symbol] =0.554ρ^{-1/3} for each density ρ, demonstrating a boundary between dimensionalities. At the right in FIGS. 3B and 3C are line-cuts of μ and σ, respectively, at densities of 1, 5, and 9 ppm (data points indicated by squares, circles, and crosses, respectively). The inset in FIG. 3C shows σ at multiple densities with thickness normalized by [symbol] rₙₙ [symbol] .

FIGS. 3D and 3E are plots of the mean u and variance σ², respectively, of coherence-time distributions of T₂ a function of P1 density and layer thickness. Values are linearly interpolated between datapoints. At the right in FIGS. 3D and 3E are line-cuts of μ and σ, respectively, at densities of 1, 5, and 9 ppm (data points indicated by squares, circles, and crosses, respectively).

FIG. 4A is a plot obtained with double electron-electron resonance (DEER) spectroscopy with an NV center. This plot confirms the presence of a P1 center electron spin bath. The marked values of ƒ_{P1} correspond to P1 ESR transitions for a static magnetic field of 311 G and internal P1 hyperfine parameters.

FIG. 4B is a plot of

$$1 / {T}_{2}^{*}$$

deconference rates extracted from Ramsey interferometry measurements.

FIG. 4C is plot of compiled decoherence rates for eight measured NV centers (the two right-most points overlap) are overlaid with the probability function P, drawn directly from the histogram of computed coherence times. The height of each data point indicates the calculated probability for each value for that time and does not represent an experimental value.

FIG. 5A is a plot of the likelihood of the dataset in FIG. 4C, calculated for each set of bath parameters, from theoretical results.

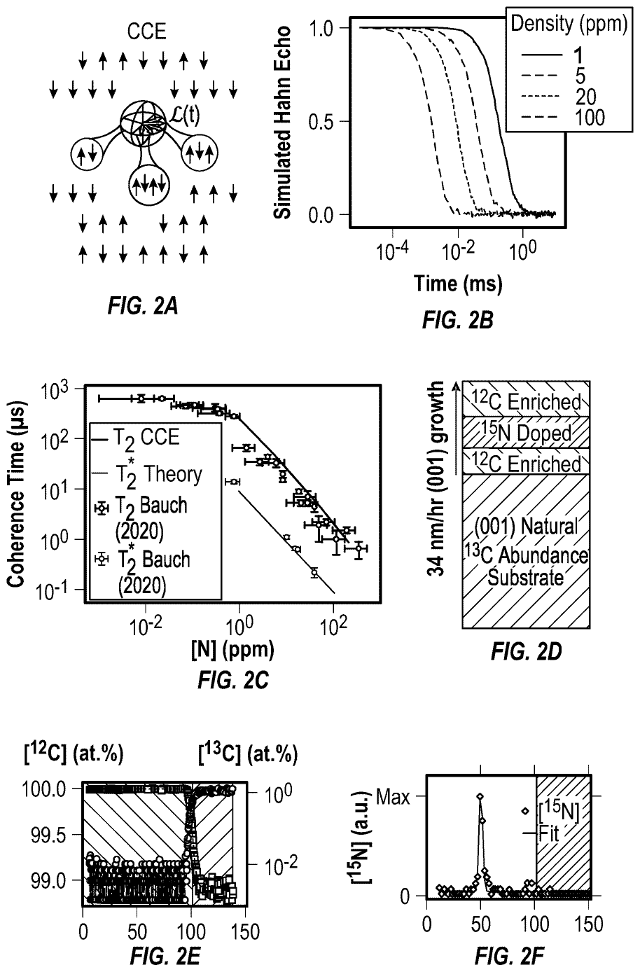

FIG. 5B is a plot of the likelihood of FIG. 5A, restricted to a thickness of t_{SIMS}=4 nm (see FIG. 2E), from which we extract a density of 3.6(7) ppm.

FIG. 5C is a plot of the calculated error of density estimation across the full density range with fixed thickness, calculated for 200 random datasets at each density.

FIG. 6A is a plot of the computed distribution of ratio of nearest-neighbor P1 coupling to background decoherence rate for 10⁵ 3-ppm density P1 bath configurations with varying thickness. Curves are offset for clarity. Shaded regions right of the dashed line indicate v≥2π.

FIG. 6B is a plot of the percentage of NV-P1 bath systems with at least one strongly coupled bath spin for varying bath density and thickness. Average spin-spin distance is marked atop curves for each density.

FIG. 7A is a plot illustrating convergence of T₂ coherence times, as calculated with CCE, with increasing CCE order.

FIG. 7B is a plot illustrating convergence of

$${T}_{2}^{*}$$

coherence times, as calculated with CCE, with increasing CCE order.

FIG. 7C is a plot illustrating convergence of T₂ coherence times, as calculated with CCE, with increasing number of simulated bath spins.

FIG. 7D is a plot illustrating convergence of T₂ coherence times, as calculated with CCE, with increasing number of simulated bath spins.

FIG. 8 shows plots of maximum likelihood estimation on a test dataset of four NV centers generated from calculations of coherence times for a 3-nm-thick 5-ppm bath.

FIG. 9A is a plot of calculated coupling distributions at 3 ppm for 3-nm and 50-nm baths.

FIG. 9B shows the same data as in FIG. 9A, but the coupling ratios for the two-dimensional (2D) bath are scaled by 1/\sqrt{2}.

FIG. 10 is a flowchart of a method that may be used for analyzing spin-bath-induced coherence, predicting the coherence of spin-qubit synthesis, characterizing the coherence of synthesized spin qubits, designing a spin-qubit-based experiment or apparatus, modifying a spin-bath environment after sample synthesis, or a combination thereof.

FIG. 11 is a functional diagram of a computing system that may be used for analyzing spin-bath-induced coherence, predicting the coherence of spin-qubit synthesis, characterizing the coherence of synthesized spin qubits, designing a spin-qubit-based experiment or apparatus, modifying a spin-bath environment after sample synthesis, or a combination thereof.

### DETAILED DESCRIPTION

### I. Introduction

Defect color centers in diamond [1,2] have been demonstrated as quantum magnetometers [3-11] and nodes in quantum communication networks [12-16]. Quantum applications of the negatively charged nitrogen-vacancy (NV) center, with a spin-photon interface and coherent operation up to and above room temperature [1, 17-19], benefit from interfacing the central NV spin qubit with accessible dark spins in the diamond lattice for quantum memories [20-22] and many-body metrological states [23-25]. These applications could enable scalable quantum networks and quantum sensing beyond the standard quantum limit. Explorations of such multi-spin systems have relied on NV centers that either occur naturally [15, 16, 21, 22, 26, 27], precluding scalability, or that are formed via nitrogen implantation [28-35], which introduce qubit decoherence sources and are associated with crystal damage [36].

Diamond-based quantum applications benefit greatly from the ongoing optimization of bottom-up color center synthesis via plasma-enhanced chemical vapor deposition (PECVD) [37-40]. Delta (8)-doping studies [41-43] have demonstrated vacancy diffusion-limited spatially localized NV centers that avoid the crystal damage and processing inherent to aperture mask or focused implantation [42, 44-49]. PECVD of diamond quantum systems has enabled engineering of NV center spin environments via isotopic purification [41, 50, 51], dimensionality control [41, 52, 53], and co-doping techniques [54-56]. However, the development of these techniques has outpaced computational efforts to model spin bath-induced decoherence [57, 58] and theoretical approaches have not yet been applied to investigate diamond qubit synthesis. Cluster correlation expansion (CCE) techniques provide an accurate approach to model decoherence in varied and tailored electron and nuclear spin bath environments [59]. Such techniques have recently been applied to study material systems relevant for quantum applications [58, 60-62], indicating that CCE may be a powerful tool to enable more efficient synthesis procedures, which are crucial for the design of quantum materials [63].

In some of the present embodiments, we apply CCE techniques, as implemented in the open source framework PyCCE [60], to predict and characterize bottom-up solid-state spin-qubit synthesis. We first introduce the computation and materials growth techniques. We then explore a common electronic spin defect created during NV center synthesis: the neutrally charged substitutional nitrogen

$${N}_{s}^{0}$$

with electron spin S=½ (P1 center). Using theoretical predictions, we investigate the P1 center electron spin bath-induced decoherence [57, 64] of NV centers in diamond across the parameter space of our growth regime (P1 density and layer thickness). We focus on low-dimensional spin bath geometries, finding central spin lifetime-limited coherence times and a non-trivial dependence of single spin coherence times on dimensionality. Obtained dependencies enable the use of coherence time distributions as descriptors of these systems for determining the growth parameters. To this end, we develop a maximum likelihood estimation (MLE) model based on Ramsey

$${T}_{2}^{*}$$

coherence times and apply it to characterize nitrogen incorporation in a experimental test sample. We then study low-dimensional electron spin baths as hosts to strongly coupled electron spin systems, demonstrating how our computational techniques can help improve the yield of future quantum devices and aid in experimental design.

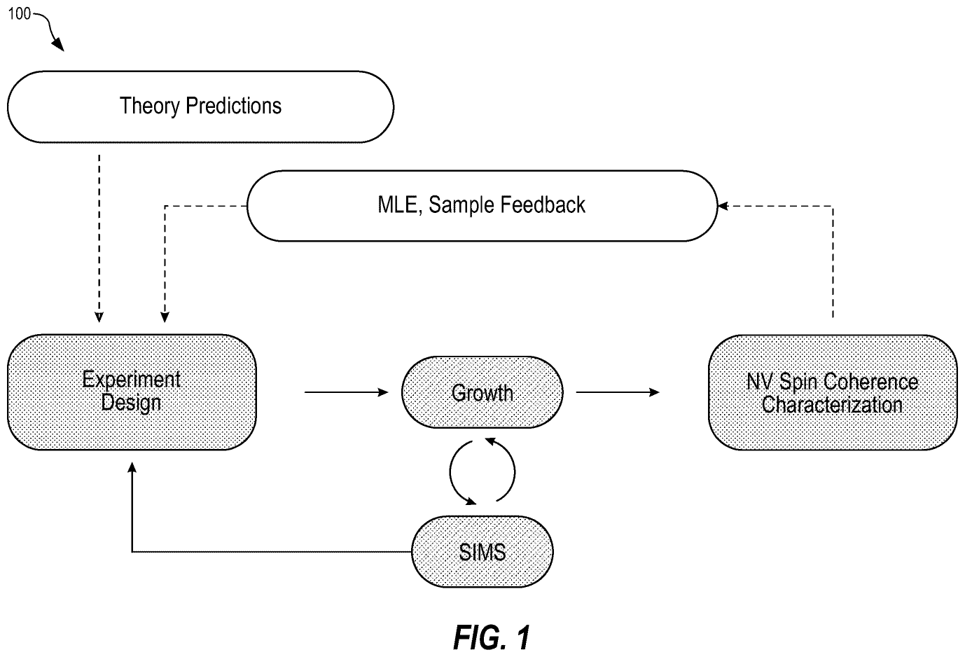

FIG. 1 is a flow chart of a method 100 for synthesizing NV centers, in accordance with the present embodiments. Within FIG. 1, the shaded boxes illustrate a prior-art method for NV-synthesis and experimental design. After identifying a target sample density and geometry, iterations of growth and secondary ion mass spectrometry (SIMS) are used to confirm the nitrogen doping density. In practice, we have observed large variations in SIMS results that reduce the efficacy of this approach, as discussed in Sec. IIB. As compared to the prior-art method, the method 100 advantageously incorporates theoretical spin-bath predictions and an in-situ density characterization tool (see the unshaded boxes in FIG. 1). The understanding of low-dimensional spin bath decoherence obtained through theory and computation improves initial experimental design. Furthermore, the local density feedback enabled by the MLE model circumvents the need for SIMS characterizations of doping density. The new technique for in-situ measurement of spin-bath density additionally opens a path to study post-growth modification of spin-bath environments [65].

### II. Results

### A. Validation of Theoretical Calculations

Within the CCE approach [66, 67], the coherence function [symbol] (t)= [symbol] 0|\hat{ρ}(t)|1 [symbol] / [symbol] 0|\hat{ρ}(0)|1 [symbol] , defined as the normalized off-diagonal element of the density matrix of the qubit \hat{ρ}(t), is approximated as a product of irreducible contributions of bath spin clusters, where the maximum size of the cluster n corresponds to the order n of the CCEn approximation (see FIG. 2A). We converge the calculations with respect to the size of the bath and the order of CCE approximation. We find that the Ramsey signal of the electron spin in the electron spin bath is converged at first order (CCE1), when each P1 is treated as isolated spin. We can thus solve the P1-limited Ramsey decoherence analytically and compute

$${T}_{2}^{*}$$

as a sum of the couplings between the NV center and the weakly coupled P1 centers. The Hahn echo signal is instead simulated at the CCE4 level of theory (see Methodologies for more details).

We validate our theoretical calculations against a reference dataset of NV center ensemble coherence times in bulk 14N P1 spin baths [57]. We extract T₂ from the coherence curve by fitting the signal to a stretched exponential function, exp[−(t/T₂)ⁿ], as shown in FIG. 2B. Computed ensemble

$${T}_{2}^{*}$$

and T₂, averaged over a set of random P1 positions, are overlaid in FIG. 2C with experimental data taken from Ref. [57]. We find excellent agreement with the experimental data, showing that the first-principles calculation with CCE method yields a quantitative description of the decoherence due to P1 spin baths. The stretched exponent parameter of the computed Hahn-echo decay is between n=1.2-1.3, in excellent agreement with the data of Ref. [57].

### B. Diamond Growth and Defect Synthesis

The sample studied herein, shown schematically in FIG. 2D, was grown with a 3-min, 10-sccm ¹⁵N₂ flow at a time corresponding to a depth of ~50 nm. Nitrogen δ-doping is achieved by introducing ¹⁵N₂ gas (99.99% chemical purity, 99.9 at % isotopic purity) during diamond growth. According to the SIMS characterization of a calibration sample, shown in FIGS. 2E and 2F, this creates a 3.8 (0.2)-nm thick (compared to

$$1. {3}_{- 0}^{+ 2.2}$$

nm, as predicted from growth calibrations) 15N-doped layer at a depth of 50.2 (0.1) nm, with a SIMS-quantified [¹⁵N] density of 0.39(2) ppm to 4.16(7) ppm (dependent on third-party SIMS measurement) within ¹²C isotopically purified diamond overgrowth ([¹²C]=99.993 at %). These values are obtained from a calibration sample, processed and grown identically to the sample studied herein.

While SIMS is often used for detecting low concentrations of dopants in semiconducting materials, sample geometries unique to our application remain difficult to characterize accurately due to experimental limitations. Specifically, the trade-off between depth resolution and overall sensitivity is dictated by the analysis/sputtering energy. Under our characterization conditions, the ideal detection limits for ¹⁵N and ¹⁴N densities are 1×10¹⁵ cm⁻³ (≈0.006 ppm) and 7×10¹⁵ cm⁻³ (≈0.04 ppm), respectively. However, the obtained densities can vary significantly as a function of sample inhomogeneities, the presence of growth defects, and experimental conditions. While studying samples that were nominally grown under the same conditions, SIMS quantification of [¹⁵N] has been observed to regularly vary by at least an order of magnitude, requiring rigorous statistics over growth of multiple samples, a time- and resource-consuming process. A truly local spin-defect materials characterization method is necessary, motivating the in-situ maximum likelihood estimation of the density characterization presented in Sec. IIE, a new capability enabled by our computational results.

A recently developed complementary approach analyzes the effect of spin-bath density and dimensionality on the shape of the exponential coherence decay of ensembles of NV centers [52, 53]. The present embodiments, in contrast, can operate in a single NV-center regime—relevant for many NV center applications—and relies on converged, experimentally verified calculations rather than an analytical treatment of the underlying physics of spin-bath noise. Both approaches address the need for accurate characterization of quantum platforms.

### C. Single Spin Coherence in Quasi-2D Electron Bath

We investigate single-spin coherence properties across the parameter space spanning the ranges of spin-bath density and spin-bath thickness that can be experimentally attained with the PECVD growth recipe adopted herein and described in more detail below (see Methodologies). The spin-bath density and spin-bath thickness are both examples of spin-bath parameters that characterize the spin bath. While the examples herein use these two spin-bath parameters, it should be understood that the present embodiments can be used for other types of spin-bath parameters. Also, it should be clear to those trained in the art how to alter the present embodiments to accommodate more than two spin-bath parameters.

To generate the coherence model, we compute Ramsey convince time

$${T}_{2}^{*}$$

(see FIG. 3A, left) for each of 10⁴ theoretical spin baths whose spin-bath thickness t varies between 0.5 and 12 nm in 0.5 nm steps, and whose spin-bath density ρ varies between 0.5 and 12 ppm in 0.5 ppm steps. The resulting 10⁴ coherence times

$${T}_{2}^{*}$$

are computed to account for coupling between the central NV-center electron spin and the spin bath. The term “spin-bath configuration” is used herein to refer to all combinations of values of the spin-bath parameters. In the present example, there are 576 spin-bath configurations, each having both one value for the spin-bath thickness t and one value for the spin-bath density ρ. Accordingly, each spin-bath configuration can be represented by the 2-tuple (t, φ.

Each theoretical spin bath has a plurality of N bath spins. For example, the N bath spins may be N electrons for the case of a P1 spin bath. Each of the N bath spins is coupled to the center spin (see Methodologies). The number N of bath spins may be predetermined (see Sec. S.I.B below). For each spin-bath configuration, the spatial coordinates of each bath spin are randomly generated such that the resulting values of the parameters of the theoretical spin bath match those of the spin-bath configuration.

Another coherence model was constructed by simulating Hahn-echo measurements (see FIG. 3A, right) for each of 201 theoretical spin baths whose spin-bath thickness t varies between 1 and 10 nm in 1 nm steps, and whose spin-bath density ρ varies between 1 and 12 ppm in 1 ppm steps. Thus, this second coherence model has 120 spin-bath configurations (t, ρ). See Sec. S.I.B for justification of CCE order.

We characterize the distributions of the coherence times with the mean u and the variance σ² of the logarithm of the coherence times at each value of the spin-bath density and each value of the spin-bath thickness (see FIGS. 3B-3E). For the computed values of

$${T}_{2}^{*} ,$$

the mathematical formulas for the mean μ and variance σ² are

$$μ = 1 {0}^{〈 {log}_{10} ( {T}_{2}^{*} / [ 1 ms ] ) 〉}$$

and variance

$${σ}^{2} = 〈 {log}_{10}^{2} ( {T}_{2}^{*} / [ 1 ms ] ) 〉 - {〈 {log}_{10} ( {T}_{2}^{*} / [ 1 ms ] ) 〉}^{2} .$$

For the computed values of T₂, the mathematical formulas for the mean μ and variance σ² are μ= [symbol] and variance

$${σ}^{2} = 〈 {log}_{10}^{2} ( {T}_{2} / [ 1 ms ] ) 〉 - {〈 {log}_{10} ( {T}_{2} / [ 1 ms ] ) 〉}^{2} .$$

Using the logarithm of the coherence, we can directly compare the coherence distributions at different timescales.

FIGS. 3B and 3C depict μ and σ, respectively, over the chosen ranges of values of the spin-bath parameters (t, ρ) for

$${T}_{2}^{*} .$$

FIGS. 3D and 3E depict μ and σ, respectively, over the chosen ranges of values of the spin-bath parameters (t, ρ) for T₂. In each case, the computed average coherence times u decrease with increasing spin-bath density ρ and/or increasing spin-bath thickness t, as expected. In the three-dimensional limit, the average coherence time μ is independent of the spin-bath thickness t. The observed decrease in μ as a function of spin-bath thickness t (see FIGS. 3B and 3D) suggests the presence a low-dimensional spin-bath regime in the chosen range of spin-bath parameters (t, ρ).

We analytically derive the distribution of the interaction strength between the central spin and bath spins in low-dimensional baths in Sec. IIF. In the case of T₂, we predict coherence times exceeding 1 ms in the bottom-left half of the parameter space in FIG. 3D, beyond what is generally observed in experiment. This suggests that experimental T₂ times in thin, low-density spin baths are limited by noise sources not captured in our model, as suggested previously [57]. However, our calculations predict that, in principle, low-dimensional lightly doped samples can realize T₁ limited coherence times at room temperature.

Bath dimensionality further impacts the relative distribution of coherence times, described by the standard deviation σ. Focusing on the inhomogeneous dephasing time

$${T}_{2}^{*}$$

(see FIG. 3C, right), σ exhibits unexpected behavior in the region where the thickness equals the average nearest-neighbor distance in three dimensions (denoted [symbol] rⁿⁿ [symbol] ) plotted as a function of density in the left plot. Here, σ plateaus when the thickness is smaller than [symbol] rₙₙ [symbol] and decreases when thicknesses are larger. The inset in FIG. 3C, right, demonstrates universal behavior of coherence times relative to the bath dimensionality. The x-axis is normalized to [symbol] rₙₙ [symbol] . This indicates that two-dimensional spin baths naturally have a wider spread of NV-center coherence times. While thin and less dense samples may optimize coherence times, they typically also lead to greater fluctuations in single-qubit coherence properties.

We see similar trends in Hahn-echo T₂ times (see FIG. 3E, right) of the second coherence model. In general, we find that

$${σ}_{{T}_{2}^{*}} > {σ}_{{T}_{2}} .$$

In Sec. S.I.C, we find that

$${T}_{2}^{*}$$

and T₂ converge at 10 and 100 bath spins, respectively, suggesting heuristically that Ramsey measurements are sensitive to the variation of a fewer number of bath spins. In general, one expects a smaller standard deviation in physical quantities that are sensitive to larger numbers of randomly placed spins due to the central limit theorem. We thus expect a larger impact of the stochasticity in P1 position on the

$${T}_{2}^{*}$$

distributions. These results inform solid-state qubit synthesis characterization, where both

$${T}_{2}^{*}$$

and T₂ are standard measurements performed on multiple NV centers.

Our theoretical results constitute a full computational characterization of spin-bath-induced coherence times across a range of spin-bath configurations. Our computational strategy is not limited to NV centers in diamond and can be applied to other spin-defect systems as well as other spin-bath measurements, provided that the appropriate pulse sequence can be emulated using the PyCCE code. Additionally, our approach will inform future diamond growth and NV synthesis. Rather than extrapolating from bulk data or measurements on single δ-doped NV centers, growth may now be informed by the theoretical predictions of coherence-time distributions.

### D. Sample Characterization

We characterize the coherence of an exemplar sample grown under the conditions outlined in Sec. IV B. FIG. 4A presents frequency-dependent double electron-electron resonance (DEER) measurements of a single NV center in a P1 center bath. This measurement essentially performs electron spin resonance (ESR) spectroscopy on target spins (here P1 center electron spins) by recoupling their dipolar interactions to the NV center probe spin, which are otherwise decoupled by the Hahn-echo sequence. At the experimental magnetic field of 311 G, and given ¹⁵N P1 hyperfine couplings, we expect, based on the possible P1 Jahn-Teller axis directions and ¹⁵N nuclear spin states (see Methodologies), transitions near 935 MHz and 954 MHz for the four possible [symbol] 111 [symbol] crystallographic axes, respectively, and the nitrogen nuclear spin state +½ probed here. We observe resonances at microwave frequencies ƒ_{P1} of 934.8 MHz (ƒ_{P1,3/8}) and 953.1 MHz (ƒ_{P1,1/8}), where the subscripts indicate the fraction of the bath probed at that frequency. This confirms the presence of ¹⁵N P1 centers in the sample.

We measure

$${T}_{2}^{*}$$

times for a set of eight single NV centers in the same test sample. FIG. 4B shows characteristic Ramsey interferometry data for one of these NV centers. Data is fit to decay with oscillations capturing the coupling to single nearby P1 centers, as in the Ramsey analysis in Sec. II. While the ¹⁵NV center exhibits a ≈3 MHz splitting from its nitrogen nuclear spin, it does not contribute to NV center decoherence rate and thus is not included in CCE calculations. We are careful to drive with 909-kHz Rabi-rate pulses to avoid mixing nuclear hyperfine effects into our measurement. This NV center exhibits

$${T}_{2}^{*} = 25 ( 2 )$$

μs (see Sec. S.III for details of measurements). This process is repeated for eight NV centers.

Decoherence rates for the set of measured NV centers are plotted in FIG. 4C along with the calculated probability distribution function (PDF) that best fits the measured distribution as determined via MLE, discussed in the next section. The aim in the following section will be to determine which calculated distribution best fits this dataset.

### E. Maximum Likelihood Estimation

Using the theoretical dependence of the coherence-time distributions on spin-bath thickness t and spin-bath density p, we now develop the maximum likelihood estimation (MLE) model to recover the growth parameters of the given sample. This procedure determines what distribution best predicts the measured coherence time

$$\{ {T}_{2}^{*} \}$$

shown in FIG. 4C.

The likelihood L of obtaining a given spin-bath configuration (t, ρ) is calculated as the joint probability of measuring the dataset

$$\{ {T}_{2}^{*} \}$$

for the given spin-bath configuration [68]

$$L ( t , ρ ) = {\prod }_{i} P ( 1 / {T}_{2 , i}^{*} \vert t , ρ ) , \qquad ( 1 )$$

where the function P approximates the probability density function of the coherence time

$${T}_{2}^{*}$$

at the given spin-bath configuration (t, ρ). The function P is obtained from the (first) coherence model described above in Sec. II.C. When evaluated,

$$P ( 1 / {T}_{2 , i}^{*} \vert t , ρ )$$

gives the relative likelihood of measuring the rate

$$1 / {T}_{2 , i}^{*}$$

(again, at the given spin-bath configuration (t, ρ)). The value

$$P ( 1 / {T}_{2 , i}^{*} \vert t , ρ )$$

is also referred to herein as the “partial probability density.” the likelihood L(t, ρ) is also referred to herein as the “total probability density.”

In some embodiments, the function P is obtained by applying a curve-fitting technique to the values of

$${T}_{2}^{*}$$

computed for the spin-bath conguration (t, ρ). For example, the 10⁴ values of

$${T}_{2}^{*}$$

generated for the spin-bath configuration (t, ρ) (as described above in Sec. II.C) can be binned into a histogram. The curve-fitting technique can then be applied to this histogram to obtain the function P. Examples of curve fitting that may be used include, but are not limited to, curve fitting (e.g., spline curve, piecewise linear, etc.), smoothing, and least-squares regression (e.g., Levenberg-Marquardt algorithm). Once the function P is obtained, it can be evaluated at all of the measured coherence times

$${T}_{2 , i}^{*}$$

to obtain all of the partial probability densities

$$P ( 1 / {T}_{2 , i}^{*} \vert t , ρ )$$

for the spin-bath configuration (t, ρ).

Instead of curve-fitting, the function P may be assumed to have a particular mathematical form that can be constructed from simple statistics that are obtained from the computed coherence times for the spin-bath configuration (t, ρ). For example, the function P may be assumed to be a Gaussian probability density function having the mean u and variance σ², as described above and shown in FIGS. 3B-3E. In this case, a Gaussian probability density function is fully characterized by two simple statistics: the sample mean and the sample variance. As an alternative to a Gaussian, the function P can have a different mathematical form that can be constructed from additional or alternative simple statistics.

Using Eqn. 1, the likelihood L(t, ρ) is evaluated for each of the spin-bath configurations (t, ρ) used to construct the coherence models described in Sec. II.C. FIG. 5A is a plot of the likelihood L(t, ρ) over all of the spin-bath configurations (t, ρ) and for the measured coherence times shown in FIG. 4C. We find a band of potential bath geometries that satisfy the observed coherence time distribution rather than uniquely predicting a single set of values. Based on the CVD growth discussed in Sec. IV-B, we estimate the bath thickness to be t_{SIMS}=4 nm. FIG. 5B is a plot of the linecut L(t_{SIMS}, ρ), which provides a measure of the spin-bath density of 3.6(7) ppm, where the error is found by fitting L(t_{SIMS}, ρ) to a normal distribution. This density estimation is not subject to the variation observed in SIMS measurements quoted in Sec. II B. In Sec. S.IV, we explore how adding more complex coherence measurements, such as Hahn echo, to the MLE procedure improves the identification of both thickness and density, at the expense of experimental time and complexity.

We benchmark the error in the MLE procedure versus the number of coherence time samples in FIG. 5C. For each number N of samples and spin-bath configuration (t, ρ), 200 randomly generated

$${T}_{2}^{*}$$

datasets of N coherence times are chosen from the numerical datasets used in Sec. II. Then, the likelihood L(t₀, ρ) is calculated for a fixed thickness t₀, and the relative error for one dataset is calculated as

$${ϵ}_{{ρ}_{0}}^{2} = {( {ρ}_{m l e} - {ρ}_{0} )}^{2} / {ρ}_{0}^{2} ,$$

where ρₘₗₑ is the density such that L(t₀, ρₘₗₑ)=max[L(t₀, ρ)]. This is averaged over a range of tested densities, plotted in FIG. 5C. We calculate the error for eight samples to be 25%, corresponding to an uncertainty of 0.9 ppm for the density estimate from FIG. 5A. This is similar to the error from fitting L, and is stable when the thickness is varied. We fit the average error as A. N^{-P}, shown over the calculated error in FIG. 5C, finding a N^{-0.55} trend.

### F. Strong Coupling Yield

Entangled qubit-based sensors promise to greatly enhance quantum sensing capabilities as compared to the current state-of-the-art [24, 25]. The applicability of these schemes is enabled by high-yield synthesis of strongly coupled quantum systems (NV center spins and multiple single bath spins). We consider the impact of growth dimensionality on the yield of such systems analytically, quantifying our results with numerical predictions. In our calculations we consider central NV center spins and P1 center bath spins, but our approach is easily generalized to other spin systems.

Each bath spin couples to the NV center with a dipolar coupling strength

$${A}_{z}^{i} .$$

The NV center coherence in the absence of dynamical protocols and coupled to a bath of many weakly coupled spins can be described as a product of individual coupling contributions (see Methodologies).

We aim to describe how likely the coupling to the nearest spin, A₀, is to be greater than the dephasing from the rest of the bath, A_{bath}. The distributions of nearest neighbor distance rₙₙ in two and three dimensions are

$${g}_{2 D} = exp ( - π {r}_{n n}^{2} ϛ ) ϛ 2 π {r}_{nn} , \qquad ( 2 )$$

$${g}_{3 D} = exp ( - 4 π {r}_{n n}^{3} ρ / 3 ) ρ 4 π {r}_{nn}^{2} , \qquad ( 3 )$$

where ρ is the three-dimensional (3D) density and ç=ρt is the two-dimensional (2D) density for bath thickness t nominally less than the average nearest neighbor distance. Notably, the distributions depend on the bath dimensionality. The bath decoherence can be estimated as follows

$${Γ}_{2 D}^{b a t h} ∝ \sqrt{{\sum }_{2 D} {\vert 1 / {r}^{3} \vert}^{2}} = \sqrt{{\int }_{0}^{∞} dr 2 π r ϛ {r}^{- 6}} , \qquad ( 4 )$$

$${Γ}_{3 D}^{b a t h} ∝ \sqrt{{\sum }_{3 D} {\vert \frac{1}{{r}^{3}} \vert}^{2}} = \sqrt{{\int }_{0}^{∞} dr 4 π {r}^{2} ρ {r}^{- 6}} . \qquad ( 5 )$$

We now define the visibility v of the nearest neighbour spin as a ratio between its coupling to the central spin A₀ and the decoherence rate induced by all other spins A_{bath}

$$v = \frac{\vert {A}_{0} \vert}{\sqrt{2} {A}_{b a t h}} , \qquad ( 6 )$$

and evaluate average v over many bath configurations. Assuming the point dipole approximation to compute the coupling between central and bath spins, we find the average visibility at the given dimensionality as

$$〈 {v}_{k D} 〉 = 〈 \vert {A}_{0} \vert / \sqrt{2} {A}_{b a t h} 〉 ≃ 〈 {r}_{n n}^{- 3} / \sqrt{2} {Γ}_{k D} 〉 ,$$

where the distributions Γ_{kD} (k={2,3}) are given by Eqns. 2 and 3. We note here that averaging Γ_{kD} assumes the dephasing rate due to the rest of the spin bath follows a highly peaked distribution. We then ask if this average is larger for lower dimensional spin baths by evaluating

$$\frac{{v}_{2 D}}{{v}_{3 D}} = \frac{〈 {r}_{nn}^{- 3} / {Γ}_{2 D} 〉}{〈 {r}_{nn}^{- 3} / {Γ}_{3 D} 〉} = \sqrt{2} . \qquad ( 7 )$$

We find that the visibility of the nearest neighbor spin is \sqrt{2} larger in the 2D case, indicating that the yield of strongly coupled bath spins is significantly higher in low-dimensional systems.

We confirm these analytical predictions with numerical simulations. Using the PyCCE code, we generate 10⁵ 50 nm-thick P1 electron spin baths in a (001)-oriented diamond lattice whose densities range over two orders of magnitude, and divide each bath into slices of varying thickness. For each density and thickness, we compute the visibility v (see Eqn. 6). Representative histograms for 3-ppm spin baths are shown in FIG. 6A. As the bath thickness decreases, the visibility distribution shifts to higher values, in line with the prediction from Eqn. 7. We follow the criterion described in the Methodologies and Eqn. 11 below to identify strongly coupled bath spins. We set a threshold for the visibility at v≥2π. At this value, coherence goes through a full oscillation period when the signal contrast reaches 1/e.

We plot the resulting probability of obtaining strongly coupled spins in FIG. 6B for each density. At all densities, the likelihood of finding a NV-spin bath configuration with the desired coupling ratio is almost three times as high in the thin bath limit. Furthermore, there is a crossover transition for each density from three-dimensional to two-dimensional behavior, which intersects with the average nearest neighbor spacing [symbol] rₙₙ [symbol] =0.554ρ^{-1/3}, obtained from Eqn. 3. Heuristically, as the thickness reduces below [symbol] rₙₙ [symbol] , there are no spins proximal to the central spin in the out-of-plane direction, only in the plane of the central spin. In Sec. S.V, we present a point of comparison between the analytical and numerical approaches, finding agreement between calculated coupling distributions and the result in Eqn. 7.

### III. Outlook

Point-defects in diamond and other wide-bandgap semiconductors are promising platforms for qubit-based sensors. Deterministic synthesis of such systems will benefit from feed-forward techniques that optimize host crystal parameters for specific outcomes and applications. Additionally, such systems pave the way for entangled qubit-based sensors which hold great promise to enhance current quantum sensing capabilities. In this paper, we have demonstrated holistic quantum simulations of NV center coherence, with techniques applicable to other spin defects, as a tool for quantum system coherence characterization driven synthesis, minimizing the need for large-scale and destructive materials characterization. Practically, we showed how our approach allows for the use of rudimentary

$${T}_{2}^{*}$$

measurements to approximate in-situ doping densities, even with little prior sample knowledge. Specifically, we have demonstrated a MLE model based on a CCE-generated distribution library as an aid to process calibration and sample characterization. This method is non-destructive and operates at the density scales relevant for quantum technologies.

Additionally, the coherence distribution results presented herein explore the expected sample properties in low-dimensional spin baths. By going beyond approximate analytical treatments and sampling over a wide distribution of random bath configurations with a range of central spin-bath couplings, the CCE calculations quantitatively capture the connection between bath geometries and coherence time distributions, providing an invaluable analytical tool for experimental design.

While in this work we focus on a single dominant spin bath species in low-dimensional geometries, our MLE method is not limited to this regime. CCE techniques can readily be extended to additional spin bath species in diamond, as well as mixed nuclear and electronic spin baths. By calculating coherence times in these other situations, dopant densities in samples with multiple dominant noise sources can be characterized. Furthermore, the strategy presented here can be applied to other solid state hosts where qubit coherence is limited by spin-bath noise.

### IV. Methodology

Our work builds on two previously established techniques, CCE calculations [66, 67] and PECVD synthesis of NV centers in diamond as described below and in FIG. 2. We focus on the 15N isotope of nitrogen for the majority of the calculations as this allows us to experimentally distinguish intentionally doped defects from background occurring defects [29, 41].

### A. Theory

The dynamics of the systems are simulated using the following Hamiltonian:

$$\hat{H} = - {γ}_{e} {B}_{z} {\hat{S}}_{z} + D {\hat{S}}_{Z}^{2} + {\sum }_{i} a ( {m}_{i} ) {\hat{P}}_{z , i} - {γ}_{e} {B}_{z} {\hat{P}}_{z , i} + {\sum }_{i} S {A}^{i} {P}_{i} + {\sum }_{i \neq j} {P}_{i} {J}^{i j} {P}_{j} , \qquad ( 8 )$$

where γₑ is the electron spin gyromagnetic ratio, B_{z} is the magnetic field aligned with the z-axis, S=(Ŝₓ, Ŝ_{y}, Ŝ_{z}) are NV center spin operators, D is the NV zero field splitting, P=(\hat{P}ₓ, \hat{P}_{y}, \hat{P}_{z}) are spin operators of the P1 center, and a(mᵢ) is the hyperfine coupling between the P1 ¹⁵N nuclear spin and the P1 electron spin, dependent on the random orientation of the Jahn-Teller axis along one of four crystal directions and the nuclear spin state for each P1 (mᵢ), where i runs over all the simulated P1 centers [69]. Aⁱ are dipolar couplings between the NV center and P1 centers, and J^{ij} is the coupling between two P1 electron spins. The applied magnetic field of 50 G is sufficiently past the high-field limit and these calculations translate to measurements at higher fields as well (see Sec. S.I.A).

In Secs. S.I.B and S.I.C, we show convergence tests for Ramsey and Hahn echo simulations versus both CCE order (1 and 4, respectively) and total number of simulated bath spins. We use CCE techniques with bath state sampling to achieve convergence for the electron spin bath. For each pure electron bath state the state of spin and the P1 crystallographic orientation is chosen at random. More details about the method are available in [60].

The CCE approach [66, 67] approximates the coherence function [symbol] (t)= [symbol] σ_(t) [symbol] / [symbol] σ_(0) [symbol] = [symbol] 0|\hat{ρ}(t)|1 [symbol] / [symbol] 0|\hat{ρ}(0)|1 [symbol] , the normalized off-diagonal element of the density matrix ρ_{m,n} of the qubit, where m and n are either the ground or excited spin states |0 [symbol] and |1 [symbol] , respectively. [symbol] (t) is approximated as a product of cluster contributions:

$$ℒ ( t ) = {\prod }_{i} {\tilde{L}}^{\{ i \}} {\prod }_{i , j} {\tilde{L}}^{\{ i j \}} … , \qquad ( 9 )$$

where \tilde{L}⁽ⁱ⁾ is the contribution of a single bath spin, \tilde{L}^{{ij}} is the contribution of spin pairs, and so on for higher order clusters (see FIG. 2A). The maximum size of the cluster n included in the expansion denotes the order of CCEn approximation.

The Ramsey signal is converged at the first order of CCE. As such, we can represent the high-field Ramsey coherence function in the rotating frame for a bath in a fully mixed state as [71]:

$$ℒ ( t ) \approx {\prod }_{j}^{N} cos \frac{{A}_{z}^{j} t}{2} \approx exp [ - \frac{{A}_{b a t h}^{2}}{2} {t}^{2} ] {\prod }_{i}^{n} cos \frac{{A}_{z}^{i} t}{2} = exp [ - {( \frac{r}{{T}_{2}^{*}} )}^{2} ] {\prod }_{i}^{n} cos \frac{{A}_{z}^{i} t}{2} \qquad ( 10 )$$

where.

$${A}_{b a t h}^{2} = {\sum }_{j} {( {A}_{z}^{j} )}^{2} / 4 , {T}_{2}^{*} = \sqrt{2} / {A}_{b a t h} ,$$

the index i goes over only the n strongly coupled P1 centers, and the index j goes over all other P1s. We define strongly coupled bath spins as those distinguishable from the background decoherence, setting threshold for its visibility (Eqn. 6) as:

$${v}_{i} = \frac{\vert {A}_{z}^{i} \vert}{2} \geq 2 π \cdot \frac{{A}_{b a t h}}{\sqrt{2}} , \qquad ( 11 )$$

so that at least one full period of oscillation of the coherence function is visible when the signal contrast reaches 1/e. For each random bath configuration we order the P1 spins by strength of the coupling, and one-by-one select out the strongly coupled spins until the condition of Eqn. 11 is violated.

$${T}_{2}^{*}$$

is then recovered from the coupling to the remaining bath spins.

Ref [58] shows that CCE at second order can be used to qualitatively recover the behavior of T₂ coherence times in the P1 bath. We further extend this approach, and converge CCE Hahn echo calculations at fourth order with bath-state sampling (see Sec. S.I.B and FIG. 7C).

### B. Materials Growth

All defects studied in this work are doped in-situ during diamond PECVD with subsequent electron irradiation and annealing for NV center activation. This recipe constitutes our standard PECVD process for growing isotopically pure diamond with isotopically tagged NV centers, as shown in FIG. 2D. High-purity electronic-grade (≤10 ppb) diamond substrates measuring 2 mm×2 mm×0.5 mm and having a [symbol] 001 [symbol] growth face and [symbol] 110 [symbol] sides (Element Six) were used as starting substrates. The as-received substrates were chemical-mechanical polished (CMP) to a surface roughness of R_{q}≤0.4 μm by Syntek, LLC. Subsequently, these substrates were inductively coupled plasma reactive ion etched (ICP-RIE) to remove ≈2.5 μm of damaged diamond surface using a composite, cycled Ar/Cl₂ and O₂ plasma etching recipe. Pre-growth, the samples were annealed at 1200° C. and tri-acid cleaned to mobilize/annihilate vacancy clusters and remove any amorphous/sp² carbon, respectively. See Sec. S.II for a more detailed description of sample processing.

Homoepitaxial growth of diamond was performed in a custom-configured PECVD reactor (Seki Diamond). The growth chamber was pumped down to 8×10⁻⁸ Torr to minimize background contamination. Thereafter, high-purity H₂ (99.99999%) was introduced into the chamber, with the process microwave power of 11.5 W mm⁻² and pressure of 25 Torr maintained throughout. The substrate temperature was maintained in the range of 800(27° C.) as tracked by an infrared pyrometer. Before introduction of the diamond growth precursor, the sample was submitted to a H₂ and O₂ etch (4% of O₂) for 5 minutes and a subsequent 20-minute etch using H₂ only, to etch away any residual surface contaminants and defects, and expose the growth surface atomic step edges [38, 73]. Thereafter, ¹²CH₄ (99.9999% chemical purity, 99.99 at % isotopic purity) is introduced as the carbon precursor. The methane-to-hydrogen ratio is maintained constant at 0.1% (H₂: ¹²CH₄=400 sccm: 0.4 sccm) as to ensure step-flow growth [38, 72]. Growth rates for the obtained films were determined to be 38(10) nm h⁻¹ via ex-situ secondary ion mass spectroscopy (SIMS) analysis averaged over six calibration substrates (e.g., ¹²C overgrowth shown in FIG. 2E).

Post-growth, bulk electron irradiation with a 2×10¹⁴ cm⁻² dose at 2 MeV and a two-hour anneal at 850° C. under an argon atmosphere converts a fraction of doped nitrogen into NV centers with [¹⁵NV]≈0.01 ppb to 0.1 ppb, with the remaining nitrogen sites persisting as (P1 centers). NV activation is intentionally performed in a vacancy diffusion-limited regime [42] in order to reliably obtain optically resolvable single NV centers. As the nitrogen doping is buried 50 nm below the diamond surface, we do not expect band-bending effects on the defect charge states [74, 75].

### S.I. Cluster Correlation Expansion

### A. High-Field Limit

Calculations are performed for a 50-G field while NV measurements are at 311 G. A main concern for CCE calculations is if the electron spins are in the high-field limit relative to other energy scales. In our case, the dipolar coupling between electron spins is the next highest energy scale after the Larmor frequency (the nuclear hyperfine, at ≈3 MHz, is not considered in CCE and is not relevant for NV decoherence in our measurements). The lowest P1 Larmor frequency at 50 G is 64 MHz. At the densities considered in this work, the smallest average spin-spin distance is 4.3 nm (12 ppm), corresponding to a dipolar coupling of ≈645 kHz, two orders of magnitude smaller than the Larmor frequency. Even accounting for variation in spin-spin position, the Larmor frequency is the dominant energy scale and 50 G is already in the high-field limit for our system. We thus expect no difference in CCE calculations at the two field values.

### B. CCE Order Convergence

We evaluate convergence in a 10 ppm, 5 nm P1 spin bath, although the convergence holds over our simulated range. We run Hahn-echo simulations on a single NV center and extract decay times for CCE-2 to CCE-5, presenting the average coherence time in FIG. 7A. Calculations converge at order 4. All Hahn-echo simulations described above are performed at fourth order. FIG. 7B shows that Ramsey simulations are consistent across all orders, indicating that the NV decoherence is dominated by dipolar coupling with single bath spins. These data are the ensemble-averaged times for many NV centers, with the spread of results shown as background shading.

C. Convergence with Number of Bath Spins

In this section, we investigate how the number of bath spins affects the convergence of our calculations, as well as draw conclusions about NV-bath measurements. In FIG. 7C, T₂ convergence for a single NV center is plotted versus the number of bath spins. We find convergence at N_{T}_{₂}=100 bath spins, setting a lower bound for all simulations described above. In FIG. 7D,

$${T}_{2}^{*}$$

converges at

$${N}_{{T}_{2}^{*}} = 10 bath spins ,$$

setting a lower bound for the Ramsey interferometry results described above.

This convergence is more than a computational exercise. This also reveals the number of bath spins necessary to fully capture the central-spin coherence, with physical meaning. First, we can intuitively see why

$${N}_{{T}_{2}} = {N}_{{T}_{2}^{*}}^{2} .$$

### From the

$${T}_{2}^{*}$$

convergence, we conclude that the NV signal is dominated by dipolar coupling to 10 bath spins. Heuristically, T₂ will be sensitive to fluctuations in these coupling strengths, a direct result of fluctuations in the energy, or the linewidth, of each bath spin. The

$${T}_{2}^{*}$$

convergence already tens us the linewidth depends on the coupling to 10 nearby spins, so we can claim that the 10 spins nearest to the NV center are further influenced by the 10 spins closest to each of them, arriving at a total of 100 spins for describing Hahn-echo decoherence.

### S.II. Materials

### A. SIMS Measurements

The concentrations [¹²C], [¹³C], [¹⁴N], and [¹⁵N] were determined via calibrated quantitative SIMS at two separate commercial laboratories (EAG Laboratories and Loughborough Surface Analysis Limited (LSAL)). The samples studied in this paper were duplicates in terms of growth and preparation conditions of those used to obtain the SIMS data. All SIMS-derived error bars presented in the text are the quantification error from a gaussian amplitude fit to the SIMS depth profiles over the detection background. The growth thickness was derived from the ¹²C-rich overgrowth layer over a natural-abundance electronic grade substrate, obtained via logistic function fitting.

The EAG calibration standard is a diamond film (3.53 g cm⁻³) on Si, which is expected to present a relative sensitivity factor with some inherent error as compared to the isotopically purified single crystal regime in which we operate. As such the quoted sensitivities of 5×10¹⁵ cm⁻³ and 1×10¹⁵ cm⁻³ for [¹⁴N] and [¹⁵N], respectively, are expected to decrease slightly. However, our concentrations are orders of magnitude larger than the detection limits. The data presented in FIG. 2E is obtained from the EAG quantification on atomic nitrogen, with the LSAL data (nitrogen-carbon dimer quantification) being in good agreement.

### B. ICP-RIE Etching

ICP-RIE etching is performed in an Oxford Lab 100 to remove the CMP induced sub-surface damage. The recipe has two distinct etch steps performed in order:
1. 10 min of Ar/Cl₂ etch: Ar 25 sccm, Cl₂ 40 sccm, 10 mTorr, 400 W ICP power, 200 W bias. Resulting in a 39.8 (60) nm min⁻¹ etch rate.
2. 1 min of O₂ etch: O₂ 50 sccm, 10 mTorr, 700 W ICP power, 100 W bias. Resulting in a 133(18) nm min⁻¹ etch rate.
   The etching steps are performed in sequence to provide a ≈533 nm etch depth per step. Due to an overabundance of caution, all the samples discussed herein were submitted to five cycles of etching for a total removal of ≈2.5 μm. Post-etching surfaces were systematically characterized via AFM to ensure R_{q}≤0.4 nm.

### C. Annealing and Cleaning

Before and after the annealing step, to remove any advantageous carbon contamination, the samples are boiled in a three acid solution: 1:1:1 NHO₃ (nitric) 68%, H₂SO₄ (sulfuric) 98%, and HClO₄ (perchloric) 70% acids (trace metal grade or better) at 200° C. for 2 h or until the perchloric boils off. These samples are then DI sonicated and dried right before any subsequent steps. The samples are subjected to two distinct annealing recipes throughout the processing. The first annealing recipe is performed post ICP-RIE surface etching:

Time (min)

| | | ° C./min (ramp) | Time |
|---|---|---|---|
| Step # | Type | or ° C. (dwell) | (min) |
| 1 | Ramp | 1.6 | |
| 2 | Dwell | 200 | 720 |
| 3 | Ramp | 1.6 | |
| 4 | Dwell | 400 | 480 |
| 5 | Ramp | 1.6 | |
| 6 | Dwell | 850 | 480 |
| 7 | Ramp | 1.6 | |
| 8 | Dwell | 1200 | 120 |
| 9 | Ramp | −5 | |

The second annealing recipe is performed post electron irradiation to mobilize the electron induced vacancies and to activate the NVs. This recipe step is performed in an atmospherically sealed (Ar) quartz tube for 2 h with a 10° C. min⁻¹ ramp.

### S.III. NV Measurements

### A. Experimental Setup for NV⁻ Characterization

Room temperature NV⁻ centers were measured in a custom-built confocal microscope with a 532 nm, free-space laser (Oxxius LCX-532S-150-CSB-PPA) and a 100×, 0.9 NA air objective (Olympus MPLFLN100X). The laser spot position is controlled with a fast steering mirror (Newport FSM-300) and a 4f lens pair. The laser is gated with an acousto-optic modulator (AOM) (Gooch & Housego) and PL is measured with a Perkin Elmer SPCM-AQR-12 photon counter. Microwave pulses are generated by a SRS SG-396 for standard Ramsey measurements, with an additional custom-built microwave signal generator based on the HMC1197 evaluation board for the DEER measurement in FIG. 4A. Both signals are amplified by a Mini-Circuits ZHL-15 W-422-S+ amplifier and gated by both a Mini-Circuits ZASWA-2-50DR+RF switch and external amplitude modulation of the signal generator. Pulses are applied to the centers via a 25-μm wire that is wire-bonded over the sample. The experiment timing is handled by a Swabian Pulse Streamer. A static magnetic field of 311 G is applied at approximately 35° to the sample surface, within a few degrees of the (111) axis.

### B. NV⁻¹ Coherence

We use the standard two-part free induction decay (FID) sequence presented in FIG. 3A, which measures both the |0 [symbol] and |−1 [symbol] projections. After applying a π/2 pulse on the NV⁻, we allow the spin to evolve for a time t before applying either another +π/2 pulse or a −π/2 pulse to project into the readout basis. A readout windows at the beginning of each laser pulse are binned as the readout signals, S_{0,-1}, and a readout window at the end is binned as a reference R which allows us to correct for slow drift over each measurement cycle. The NV coherence is calculated as

$$Coherence = \frac{{S}_{0} - {S}_{- 1}}{R} . \qquad ( S 1 )$$

In the data presented in FIG. 4B, the signal is normalized by the first data point.
S.IV. Maximum Likelihood Estimate with Both Ramsey and Hahn Echo

We can calculate the maximum likelihood across datasets of both Ramsey and Hahn echo coherence times. FIG. 8 shows the MLE for just Ramsey

$${T}_{2}^{*}$$

times, just Hann ecno T₂ times, and the combined dataset. We find that the combined dataset more precisely predicts both bath density and thickness compared to the individual datasets, suggesting that incorporating more time-expensive (both computationally and experimentally) coherence measurements may remove the need for ex-situ growth characterization.

### S.V. Analytical and Computational Coupling Ratio Comparison

In Sec. II.F, we calculate in Eqn. 6 that the coupling ratio for the nearest bath spin should be \sqrt{2} larger in a two-dimensional bath compared to a three-dimensional bath. We then use numerical simulations to analyze the incidence of strongly coupled systems. FIG. 9 presents the calculated ratios and show approximate agreement with the analytical result. FIG. 9A presents the same calculated distributions as in FIG. 5A for a 3-ppm bath. In FIG. 9B, we scale the coupling ratios in the 2D bath (at 3 ppm) by 1/\sqrt{2}, in accordance with the prediction of Eqn. 6. The distributions do not overlap exactly, but we do find agreement in the peak ratio positions (the most likely values), providing a point of comparison between the analytical and numerical approaches.

### Additional Embodiments

In accordance with some of the present embodiments, FIG. 10 is a flowchart of a method 1000 that may be used for analyzing spin-bath-induced coherence, predicting the coherence of spin-qubit synthesis, characterizing the coherence of synthesized spin qubits, designing a spin-qubit-based experiment or apparatus, modifying a spin-bath environment after sample synthesis, or a combination thereof. In some embodiments, the method 1000 starts with a plurality of measured coherence times. The plurality of measured coherence times may be received from an external computer system, such as a computer that is part of an experimental apparatus that was used to measure the plurality of measured coherence times. These measurements were performed on a solid-state sample having a plurality of spin qubits embedded within a spin bath (e.g., see FIG. 2D). Each measured coherence time corresponds to respective one of the spin qubits. In some embodiments, the spin bath is two-dimensional or less. In other embodiments, the spin bath is three-dimensional (e.g., see Sec. II.F).

In the step 1006 of the method 1000, a partial probability density is determined for both (i) each coherence time of the plurality of measured coherence times and (ii) each spin-bath configuration of a plurality of spin-bath configurations. Each spin-bath configuration may be thought of as a tuple formed by combining one value of a first spin-bath parameter and one value of a second spin-bath parameter that is different from the first spin-bath parameter. Each of these spin-bath parameters may be thought of as a variable that physically characterizes the spin bath. The plurality of spin-bath configurations “span” the first and second spin-bath parameters in that each of these spin-bath parameters takes on several different values.

In some embodiments, the first spin-bath parameter is a thickness of the spin bath and the second spin-bath parameter is a density of a species of point defect forming the spin bath. An example of such embodiments is described above in Sec. II.C. In this example, each of the spin-bath configurations is represented as a 2-tuple (t, ρ), where t is a value for the thickness of the spin bath and p is a value for the P1 density. These spin-bath configurations span values of the thickness t that are uniformly spaced by 0.5 or 1.0 nm and values of the density ρ that are uniformly spaced by 0.5 or 1.0 ppm. In general, it is not necessary for the values of any spin-bath parameter to be uniformly spaced in this manner.

In general, the present embodiments may be used with other types of spin-bath parameters. Examples of such other types include, but are not limited to, the charge state of defects, a variation in density throughout a layer (in any dimension), and a magnetic-field gradient that modifies interactions between the bath spins. Furthermore, the present embodiments may be expanded to work with more than two spin-bath parameters of the spin bath. In general, each spin-bath configuration can be represented as an n-tuple having one value for each of n different spin-bath parameters, where n is an integer greater than or equal to 2.

The result of the step 1006 is a plurality of partial probability densities, each uniquely corresponding to one of the measured coherence times and one of the spin-bath configurations. Each partial probability density is derived using a coherence model 1008 and quantifies the probability density of measuring the coherence time for the spin-bath configuration. As an example of the step 1006, Eqn. 1 shows how the function

$$P ( 1 / {T}_{2 , i}^{*} \vert t , ρ )$$

is evaluated for each of the measured coherence times

$$\{ {T}_{2}^{*} \} .$$

Furthermore, Eqn. 1 is repeated for each of the spin-bath configurations (t, ρ).

In some embodiments, the coherence model 1008 models the coherence time of one theoretical spin qubit coupled to a theoretical spin bath having a plurality of bath spins. The theoretical spin qubit is likely to, although not necessarily, be a different type of particle than that of the bath spins. In some embodiments, the method 1000 further includes constructing the coherence model 1008. The coherence model 1008 may be constructed, for example, using CCE calculations. As an example of these embodiments, Sec. II.C describes how CCE calculations can be used to develop two coherence models for one NV qubit in a bath of P1 centers. The first coherence model computes the Ramsey coherence time

$${T}_{2}^{*}$$

while the second model computes the relaxation time T₂. However, the coherence model 1008 may model a different type of coherence, qubit, spin bath, or a combination thereof.

In some embodiments, each partial probability density is determined by (i) feeding the spin-bath configuration into the coherence model 1008 to obtain a probability distribution function for the spin-bath configuration and (ii) evaluating the probability distribution function for the coherence time to obtain the partial probability density. As an example of these embodiments, Sec. II.E describes different techniques for constructing the function P from the first coherence model described in Sec. II.C. The function P may then be evaluated for each measured coherence time, as shown in Eqn. 1 for the case of

$${T}_{2}^{*} .$$

In the step 1010 of the method 1000, a total probability density is determined for each spin-bath configuration. The total probability density is derived from the plurality of partial probability densities determined in the step 1006 (for the spin-bath configuration). Each total probability density quantifies the relative likelihood of measuring all of the plurality of measured coherence times for the given spin-bath configuration. The output of the step 1010 is therefore a plurality of total probability densities in one-to-one correspondence with the plurality of spin-bath configurations. As an example of the step 1010, FIG. 5C shows a plot of the likelihood L(t, ρ), as calculated for all of the spin-bath configurations used to construct the first coherence model of Ramsey coherence time

$${T}_{2}^{*} .$$

In some embodiments, the plurality of partial probability densities are multiplied together to obtain the total probability density. In one example of these embodiments, Eqn. 1 shows how the partial probability densities

$$P ( 1 / {T}_{2 , i}^{*} \vert t , ρ )$$

for the spin-bath configuration (t, ρ) are multiplied together to obtain the likelihood L(t, ρ).

In the step 1014 of the method 1000, a value of the first spin-bath parameter is determined for the spin bath of the solid-state sample. As shown in FIG. 10, this value may be derived or inferred from one or more growth parameters 1012 used to synthesize the solid-state sample. Alternatively, the value may be obtained via a direct measurement of the solid-state sample. As an example of the step 1014, Sec. 2.E describes how the spin-bath thickness t_{SIMS}=4 nm was estimated from CVD growth parameters.

In the step 1016 of the method 1000, a value of the second spin-bath parameter is determined based on a subset of the plurality of total probability densities. Each element belonging to the subset is consistent with the value of the first spin-bath parameter determined in the step 1014. In some embodiments, the value of the second spin-bath parameter is determined by fitting the subset of total probability densities to a curve. The value of the second spin-bath parameter can then be derived from a best-fit parameter returned by the fit. As an example of the step 1016 in these embodiments, FIG. 5B shows how a linescan of the likelihood plot of FIG. 5A was fit to a Gaussian function. The best-fit center of the Gaussian gave a value for the spin-bath density of the solid-state sample.

In the step 1018 of the method 1000, the value of the second spin-bath parameter is outputted. For example, this value may be displayed on the screen of a computing device (e.g., a desktop or laptop computer, tablet, smart phone, etc.) or transmitted to another computing system. In some embodiments, an uncertainty of the value of the second spin-bath parameter is determined based on the subset of the plurality of total probability densities. This uncertainty may outputted with the value of the second spin-bath parameter.

In some embodiments, the value of the second spin-bath parameter is used to design or calibrate a quantum device that uses the solid-state sample. In some of these embodiments, the method 1000 further includes operating the quantum device.

In some embodiments, the method includes the step 1020 in which one or more subsequent growth parameters are identified based the second spin-bath parameter. These subsequent growth parameters may be outputted in lieu of, or in addition to, the value of the second spin-bath parameter. In some embodiments, the method includes a step 1022 in which a subsequent solid-state sample is synthesized, or grown, based on the one or more subsequent growth parameters. In one example of the step 1022, the subsequent solid-state sample is grown using CVD techniques (e.g., PECVD).

In some embodiments, the method 1000 includes the step 1004 in which the plurality of measured coherence times are experimentally measured using the solid-state sample. Each of the measured coherence times may be an inhomogeneous relaxation time, denoted

$${T}_{2}^{*}$$

in the art. One example of an inhomogeneous relaxation time is the Ramsey coherence time. In this case, Ramsey interferometry can be performed on each of the plurality of spin qubits in the solid-state sample to obtain a respective one of the measured coherence times. However, another type of inhomogeneous relaxation time may

$${T}_{2}^{*}$$

be used.

Alternatively, each of the measured coherence times may be a homogenous relaxation time, denoted T₂ in the art. Examples of T₂ include, but are not limited to, the spin-spin relaxation time constant, the transverse relaxation time constant, the transverse magnetization time constant, and the dephasing time. In any of these cases, the measured coherence times can be obtained experimentally by performing double resonance spectroscopy (e.g., double electron-electron resonance spectroscopy or electron-nuclear double resonance spectroscopy) or performing coherent spectroscopy with a dynamical decoupling sequence. Examples of such dynamical decoupling sequences include, but are not limited to, Hahn-echo pulse sequences, Carr-Purcell-Meiboom-Gill pulse sequences, XY—N pulse sequences (where N is the number of pulses), and multi-pulse sequences.

In some embodiments, the method 1000 includes the step 1002 in which the solid-state sample is synthesized using the one or more growth parameters 1012. An example of the step 1002 is described in Sec. IV.B above. The solid-state sample may be synthesized, or grown, using PE-CVD.

In accordance with some of the present embodiments, FIG. 11 is a diagram of a computing system 1100 that may be used for analyzing spin-bath-induced coherence, predicting the coherence of spin-qubit synthesis, characterizing the coherence of synthesized spin qubits, designing a spin-qubit-based experiment or apparatus, modifying a spin-bath environment after sample synthesis, or a combination thereof. The computing system 1100 has a processor 1102 and a memory 1110 that electronically communicate with each other over a system bus 1108. The memory 1110 stores data 1140 and machine-readable instructions 1112 that, when executed by the processor 1102, implement the functionality described herein. For example, the machine-readable instructions may implement certain embodiments of the method 1000 of FIG. 10 (e.g., the steps 1006, 1010, 1014, 1016, and 1018).

The computing system 1100 also includes one or more I/O blocks through which the computing system 1100 can communicate with peripheral devices (e.g., monitors, keyboards, storage devices, etc.). The one or more I/O blocks may also include network adapters and interfaces so that the computing system 1100 can communicate with external computers and computing devices (e.g., a desktop computer, server, smart phone, tablet, etc.). The one or more I/O blocks are also connected to the system bus 1108 and therefore can electronically communicate with the processor 1102 and the memory 1110. In the example of FIG. 11, the computing system 1100 is shown with an I/O block 1104 that receives measured coherence times 1150 (e.g., from an external peripheral or computer device). The computing system 1100 is also shown with an I/O block 1106 that transmits a second spin-bath value 1146 (e.g., to an external peripheral or computer device). However, each of the I/O blocks 1104 and 1106 may transmit or receive additional or alternative data 1140. While FIG. 11 shows the computing system 1100 with two I/O blocks, the computing system 1100 may have a different number I/O blocks without departing from the scope hereof.

The processor 1102 may be any type of circuit capable of performing logic, control, and input/output operations. For example, the processor 1102 may include a microprocessor with one or more central processing unit (CPU) cores, a graphics processing unit (GPU), a digital signal processor (DSP), a field-programmable gate array (FPGA), a system-on-chip (SoC), a microcontroller unit (MCU), an application-specific integrated circuit (ASIC), or a combination thereof. The processor 1102 may also include a memory controller, bus controller, and other components that manage data flow between the processor 1102, the memory 1110, and the I/O blocks 1104 and 1106.

In the example of FIG. 11, the data 1140 includes the measured coherence times 1150, spin-bath configurations 1142, a coherence model 1152, probability density functions (PDFs) 1154, partial probability densities 1156, total probability densities 1158, a subset 1160 of the total probability densities 1158, a first spin-bath value 1144, a second spin-bath value 1146, and one or more growth parameters 1148. The memory 1110 may store additional or alternative data 1140 than shown in FIG. 11. Although not shown in FIG. 11, some or all of the data 1140 may be stored in a secondary storage device (e.g., a hard drive or memory card) and fetched therefrom when needed.

In the example of FIG. 11, the machine-readable instructions 1112 include a CCE application (APP) 1114, a curve fitter 1116, a subset generator 1118, a PDF evaluator 1120, a PDF generator 1122, a maximum likelihood estimate (MLE) generator 1124, and a feedback synthesis application 1126. The memory 1110 may store additional machine-readable instructions 1112 than shown in FIG. 11. Although not shown in FIG. 11, some or all of the machine-readable instructions 1112 may be stored in a secondary storage device and fetched therefrom when needed.

The CCE application 1114, when executing, performs CCE computations to construct the coherence model 1152. The coherence model 1008 of FIG. 10 is one example of the coherence model 1152. The PyCCE code described above is one example of the CCE application 1114 [60].

The PDF generator 1122 uses the coherence model 1152 to generate the PDFs 1154. For each of the spin-bath configurations 1142, the PDF generator 1122 may call the curve fitter 1116 to fit simulated coherence times (for the given spin-bath configuration) of the coherence model 1152 to a curve. Alternatively, the PDF generator 1122 may call an interpolator that performs interpolation of the simulated coherence times. The PDF evaluator 1120 evaluates each of the PDFs 1154 with each of the measured coherence times 1150. The PDF evaluator 1120 returns the partial probability densities 1156. The PDF generator 1122 and PDF evaluator 1120 therefore cooperate to perform the step 1006 of the method 1000.

The MLE generator 1124 generates the total probability densities 1158. Specifically, for each of the spin-bath configurations 1142, the MLE generator 1124 calculates a respective one of the total probability densities 1158 using the partial probability densities 1156 for the given spin-bath configuration. The MLE generator 1124 therefore performs the step 1010 of the method 1000.

The subset generator 1118 identifies the subset 1160 of the total probability densities 1158 for which the spin-bath configurations 1142 are consistent with the first spin-bath value 1144. The first spin-bath value 1144 may be received directly from an external computing device. Alternatively, the first spin-bath value 1144 may be calculated from data received from the external computing device. For example, the subset generator 1118 may calculate the first spin-bath value 1144 from the growth parameters 1148 used to grow the solid-state sample (i.e., the sample from which the measured coherence times 1150 were measured).

The feedback synthesis application 1126 determines the second spin-bath value 1146 based on the subset 1160. The feedback synthesis application 1126 may call the curve fitter 1116 to perform curve fitting with the subset 1160. In this case, the second spin-bath value 1146 may be equal to, or derived from, a best-fit parameter returned by the curve fitter 1116. The subset generator 1118 and feedback synthesis application 1126 therefore cooperate to perform the step 1016 of the method 1000.

The computing system 1100 may be combined with other components and devices. For example, the computing system 1100 may be combined with a spectrometer or interferometer configured to measure the solid-state sample to obtain the plurality of measured coherence times 1150. As another example, the computing system 1100 may be combined with a thin-film deposition system (e.g., a PECVD reactor) for synthesizing the solid-state sample based on the growth parameters 1148. Alternatively, the thin-film deposition system may be used for synthesizing an additional solid-state sample (e.g., see the step 1020 of the method 1000). In this case, the computing system 1100 may store additional machine-readable instructions that identify, based on the second spin-bath value 1146, one or more subsequent growth parameters (e.g., see the step 1022 of the method 1000).

### Combination of Features

Features described above as well as those claimed below may be combined in various ways without departing from the scope hereof. The following examples illustrate possible, non-limiting combinations of features and embodiments described above. It should be clear that other changes and modifications may be made to the present embodiments without departing from the spirit and scope of this invention:
(A1) A method includes receiving, for each of a plurality of spin qubits embedded within a spin bath, a respective one of a plurality of measured coherence times. The plurality of spin qubits and spin bath form a solid-state sample. The method also includes determining, for each coherence time of the plurality of measured coherence times and each spin-bath configuration of a plurality of spin-bath configurations, a respective one of a plurality of partial probability densities. Each of the plurality of partial probability densities is derived from a coherence model and identifies a probability density of measuring said each coherence time for said each spin-bath configuration. The plurality of spin-bath configurations span first and second spin-bath parameters. The method also includes determining, based on the plurality of partial probability densities for each spin-bath configuration, a respective one of a plurality of total probability densities. Each of the plurality of total probability densities is a probability density of measuring all of the plurality of measured coherence times for said each spin-bath configuration. The method also includes determining, based on one or more growth parameters used to grow the solid-state sample, a value of the first spin-bath parameter for the spin bath of the solid-state sample. The method also includes determining, based on a subset of the plurality of total probability densities that are consistent with the value of the first spin-bath parameter, a value of the second spin-bath parameter for the spin bath of the solid-state sample. The method also includes outputting the value of the second spin-bath parameter.
(A2) In the method denoted (A1), the method further includes identifying, based on the value of the second spin-bath parameter, one or more subsequent growth parameters.
(A3) In the method denoted (A2), the method further includes synthesizing an additional solid-state sample based on the one or more subsequent growth parameters.
(A4) In the method denoted (A3), said synthesizing includes performing plasma-enhanced chemical vapor deposition.
(A5). In any of the methods denoted (A1) to (A4), the method further includes determining, based on the subset of the plurality of total probability densities, an uncertainty of the value of the second spin-bath parameter. The method further includes outputting the certainty.
(A6) In any of the methods denoted (A1) to (A5), said determining the respective one of the plurality of total probability densities includes multiplying the plurality of partial probability densities together for said each spin-bath configuration.
(A7) In any of the methods denoted (A1) to (A6), said determining the respective one of the plurality of partial probability densities includes (i) feeding said each spin-bath configuration into the coherence model to obtain a probability distribution function for said each spin-bath configuration and (ii) evaluating the probability distribution function for said each coherence time to obtain the respective one of the plurality of partial probability densities.
(A8) In any of the methods denoted (A1) to (A7), each of the plurality of qubits is a nitrogen-vacancy center in diamond.
(A9) In the method denoted (A8), the spin bath includes a plurality of P1 centers.
(A10) In any of the methods denoted (A1) to (A9), the first spin-bath parameter is a thickness of the spin bath and the second spin-bath parameter is a density of a species of point defect forming the spin bath.
(A11) In any of the methods denoted (A1) to (A10), the spin bath is two-dimensional or less.
(A12) In any of the methods denoted (A1) to (A10), the spin bath is three-dimensional.
(A13) In any of the methods denoted (A1) to (A12), the spin bath is an electron spin bath.
(A14) In any of the methods denoted (A1) to (A13), each of the plurality of measured coherence times is a respective one of a plurality of inhomogeneous relaxation times.
(A15) In the method denoted (A14), the method further includes performing Ramsey interferometry on each of the plurality of spin qubits to obtain a respective one of the plurality of inhomogeneous relaxation times.
(A16) In any of the methods denoted (A1) to (A13), each of the plurality of measured coherence times is a respective one of a plurality of homogeneous relaxation times.
(A17) In the method denoted (A16), the method further includes measuring each of the plurality of spin qubits to obtain a respective one of the plurality of homogeneous relaxation times.
(A18) In the method denoted (A17), said measuring includes performing (i) double resonance spectroscopy or (ii) performing coherent spectroscopy with a dynamical decoupling sequence.
(A19) In any of the methods denoted (A1) to (A18), the method further includes synthesizing, prior to said measuring, the solid-state sample based on the one or more growth parameters.
(A20) In any of the methods denoted (A1) to (A19), said determining the value of the second spin-bath parameter includes fitting the subset of the plurality of total probability densities, the value of the second spin-bath parameter being derived from a best-fit parameter obtained via said fitting.
(A21) In any of the methods denoted (A1) to (A19), said outputting the value of the second spin-bath parameter includes using the value of the second spin-bath parameter to design or calibrate a quantum device using the solid-state sample.
(A22) In the method denoted (A21), the method further includes operating the quantum device.
(A23) In any of the methods denoted (A1) to (A22), said outputting includes displaying the value of the second spin-bath parameter on a display.
(A24) In any of the methods denoted (A1) to (A23), the coherence model is a model of coherence time of one theoretical spin qubit, of a type of the plurality of spin qubits, coupled to a theoretical spin bath comprising a plurality of bath spins.
(A25) In any of the methods denoted (A1) to (A24), the method further includes constructing the coherence model.
(A26) In the method denoted (A25), said constructing includes performing cluster correlation expansion.
(B1) A system includes a processor and a memory in electronic communication with the processor. The memory stores machine-readable instructions that, when executed by the processor, control the system to (i) receive, for each of a plurality of spin qubits embedded within a spin bath, a respective one of a plurality of measured coherence times, the plurality of spin qubits and spin bath forming a solid-state sample; (ii) determine, for each coherence time of the plurality of measured coherence times and each spin-bath configuration of a plurality of spin-bath configurations, a respective one of a plurality of partial probability densities, each of the plurality of partial probability densities being derived from a coherence model and identifying a probability density of measuring said each coherence time for said each spin-bath configuration, the plurality of spin-bath configurations spanning first and second spin-bath parameters; (iii) determine, based on the plurality of partial probability densities for each spin-bath configuration, a respective one of a plurality of total probability densities, each of the plurality of total probability densities being a probability density of measuring all of the plurality of measured coherence times for said each spin-bath configuration; (iv) determine, based on one or more growth parameters used to grow the solid-state sample, a value of the first spin-bath parameter for the spin bath of the solid-state sample; (v) determine, based on a subset of the plurality of total probability densities that are consistent with the value of the first spin-bath parameter, a value of the second spin-bath parameter for the spin bath of the solid-state sample; and (vi) output the value of the second spin-bath parameter.
(B2) In the system denoted (B1), the memory stores additional machine-readable instructions that, when executed by the processor, control the system to identify, based on the value of the second spin-bath parameter, one or more subsequent growth parameters.
(B3) In the system denoted (B2), the system further includes a chemical vapor deposition system configured to grow an additional solid-state sample based on the one or more subsequent growth parameters.
(B4) In the system denoted (B3), the chemical vapor deposition system includes a plasma-enhanced chemical vapor deposition reactor.
(B5) In any of the systems denoted (B1) to (B4), the memory stores additional machine-readable instructions that, when executed by the processor, control the system to (i) determine, based on the subset of the plurality of total probability densities, an uncertainty of the value of the second spin-bath parameter and (ii) output the uncertainty.
(B6) In any of the systems denoted (B1) to (B5), the machine-readable instructions that, when executed by the processor, control the system to determine the respective one of the plurality of total probability densities include machine-readable instructions that, when executed by the processor, control the system to multiply the plurality of partial probability densities together for said each spin-bath configuration.
(B7) In any of the systems denoted (B1) to (B6), the machine-readable instructions that, when executed by the processor, control the system to determine the respective one of the plurality of total probability densities include machine-readable instructions that, when executed by the processor, control the system to (i) feed said each spin-bath configuration into the coherence model to obtain a probability distribution function for said each spin-bath configuration and (ii) evaluate the probability distribution function for said each coherence time to obtain the respective one of the plurality of partial probability densities.
(B8) In any of the systems denoted (B1) to (B7), each of the plurality of qubits is a nitrogen-vacancy center in diamond.
(B9) In any of the systems denoted (B1) to (B8), the spin bath includes a plurality of P1 centers.
(B10) In any of the systems denoted (B1) to (B9), the first spin-bath parameter is a thickness of the spin bath and the second spin-bath parameter is a density of a species of point defect forming the spin bath.
(B11) In any of the systems denoted (B1) to (B10), the spin bath is two-dimensional or less.
(B12) In any of the systems denoted (B1) to (B10), the spin bath is three-dimensional.
(B13) In any of the systems denoted (B1) to (B12), the spin bath is an electron spin bath.
(B14) In any of the systems denoted (B1) to (B13), each of the plurality of measured coherence times is a respective one of a plurality of inhomogeneous relaxation times.
(B15) In the system denoted (B14), the system further includes a Ramsey interferometer configured to perform Ramsey interferometry on each of the plurality of spin qubits to obtain a respective one of the plurality of inhomogeneous relaxation times.
(B16) In any of the systems denoted (B1) to (B13), each of the plurality of measured coherence times is a respective one of a plurality of homogeneous relaxation times.
(B17) In the system denoted (B16), the system further includes a spectrometer configured to measure each of the plurality of spin qubits to obtain a respective one of the plurality of homogeneous relaxation times.
(B18) In the system denoted (B17), the spectrometer is configured to perform (i) double resonance spectroscopy or (ii) coherent spectroscopy with a dynamical decoupling sequence.
(B19) In any of the systems denoted (B1) to (B18), the system further includes a chemical vapor deposition system configured to synthesize the solid-state sample based on the one or more growth parameters.
(B20) In any of the systems denoted (B1) to (B19), the machine-readable instructions that, when executed by the processor, control the system to determine the second spin-bath parameter include machine-readable instructions that, when executed by the processor, control the system to fit the subset of the plurality of total probability densities, the value of the second spin-bath parameter being derived from a best-fit parameter of the fit.
(B21) In any of the systems denoted (B1) to (B20), the system further includes a quantum device that uses the solid-state sample.
(B22) In any of the systems denoted (B1) to (B21), the system further includes a screen. The machine-readable instructions that, when executed by the processor, control the system to output the value of the second spin-bath parameter include machine-readable instructions that, when executed by the processor, control the system to display the value of the second spin-bath parameter on the screen.
(B23) In any of the systems denoted (B1) to (B22), the coherence model is a model of coherence time of one theoretical spin qubit, of a type of the plurality of spin qubits, coupled to a theoretical spin bath comprising a plurality of bath spins.
(B24) In any of the systems denoted (B1) to (B23), the memory stores additional machine-readable instructions that, when executed by the processor, control the system to construct the coherence model.
(B25) In the system denoted (B24), the machine-readable instructions that, when executed by the processor, control the system to construct the coherence model include machine-readable instructions that, when executed by the processor, control the system to perform cluster correlation expansion.

Changes may be made in the above methods and systems without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

### REFERENCES

[1] M. W. Doherty, N. B. Manson, P. Delaney, F. Jelezko, J. Wrachtrup, and L. C. Hollenberg, Phys. Rep. 528, 1 (2013).
[2] C. Bradac, W. Gao, J. Forneris, M. E. Trusheim, and I. Aharonovich, Nat. Commun. 10, 5625 (2019).
[3] G. Balasubramanian et al., Nature 455, 648 (2008).
[4] J. R. Maze et al., Nature 455, 644 (2008).
[5] B. J. Maertz, A. P. Wijnheijmer, G. D. Fuchs, M. E. Nowakowski, and D. D. Awschalom, Appl. Phys. Lett. 96, 092504 (2010).
[6] D. L. Sage, K. Arai, D. R. Glenn, S. J. DeVience, L. M. Pham, L. Rahn-Lee, M. D. Lukin, A. Yacoby, A. Komeili, and R. L. Walsworth, Nature 496, 486 (2013).
[7] L. Rondin, J.-P. Tetienne, T. Hingant, J.-F. Roch, P. Maletinsky, and V. Jacques, Rep. Prog. Phys. 77, 056503 (2014).
[8] H. J. Mamin, M. Kim, M. H. Sherwood, C. T. Rettner, K. Ohno, D. D. Awschalom, and D. Rugar, Science 339, 557 (2013).
[9] T. Staudacher, F. Shi, S. Pezzagna, J. Meijer, J. Du, C. A. Meriles, F. Reinhard, and J. Wrachtrup, Science 339, 561 (2013).
[10] F. Casola, T. van der Sar, and A. Yacoby, Nat. Rev. Mater. 3, 17088 (2018).
[11] Z. Zhao, X. Ye, S. Xu, P. Yu, Z. Yang, X. Kong, Y. Wang, T. Xie, F. Shi, and J. Du, arXiv: 2205.04415 (2022).
[12] N. Kalb, A. A. Reiserer, P. C. Humphreys, J. J. W. Bakermans, S. J. Kamerling, N. H. Nickerson, S. C. Benjamin, D. J. Twitchen, M. Markham, and R. Hanson, Science 356, 928 (2017).
[13] C. Nguyen et al., Phys. Rev. Lett. 123, 183602 (2019).
[14] C. T. Nguyen et al., Phys. Rev. B 100, 165428 (2019).
[15] M. Pompili et al., Science 372, 259 (2021).
[16] S. L. N. Hermans, M. Pompili, H. K. C. Beukers, S. Baier, J. Borregaard, and R. Hanson, Nature 605, 663 (2022).
[17] D. M. Toyli, D. J. Christle, A. Alkauskas, B. B. Buckley, C. G. V. de Walle, and D. D. Awschalom, Phys. Rev. X 2, 031001 (2012).
[18] G.-Q. Liu, X. Feng, N. Wang, Q. Li, and R.-B. Liu, Nat. Commun. 10, 1344 (2019).
[19] F. J. Heremans, C. G. Yale, and D. D. Awschalom, Proc. IEEE 104, 2009 (2016).
[20] M. Pfender, N. Aslam, H. Sumiya, S. Onoda, P. Neumann, J. Isoya, C. A. Meriles, and J. Wrachtrup, Nat. Commun. 8, 834 (2017).
[21] C. E. Bradley, J. Randall, M. H. Abobeih, R. C. Berrevoets, M. J. Degen, M. A. Bakker, M. Markham, D. J. Twitchen, and T. H. Taminiau, Phys. Rev. X 9, 031045 (2019).
[22] M. J. Degen, S. J. Loenen, H. P. Bartling, C. E. Bradley, A. L. Meinsma, M. Markham, D. J. Twitchen, and T. H. Taminiau, Nat. Commun. 12, 3470 (2021).
[23] T. Xie et al., Sci. Adv. 7, eabg9204 (2021).
[24] T.-X. Zheng, A. Li, J. Rosen, S. Zhou, M. Koppenhöfer, Z. Ma, F. T. Chong, A. A. Clerk, L. Jiang, and P. C. Maurer, npj Quantum Inf. 8, 150 (2022).
[25] C. A. Meriles, P. R. Zangara, and D. Pagliero, Adv. Quantum Technol. 2300098 (2023).
[26] R. Hanson, F. M. Mendoza, R. J. Epstein, and D. D. Awschalom, Phys. Rev. Lett. 97, 087601 (2006).
[27] H. S. Knowles, D. M. Kara, and M. Atatüre, Phys. Rev. Lett. 117, 1 (2016).
[28] J. Meijer, B. Burchard, M. Domhan, C. Wittmann, T. Gaebel, I. Popa, F. Jelezko, and J. Wrachtrup, Appl. Phys. Lett. 87, 1 (2005).
[29] J. R. Rabeau, P. Reichart, G. Tamanyan, D. N. Jamieson, S. Prawer, F. Jelezko, T. Gaebel, I. Popa, M. Domhan, and J. Wrachtrup, Appl. Phys. Lett. 88, 1 (2006).
[30] T. Gaebel et al., Nat. Phys. 2, 408 (2006).
[31] P. Neumann et al., Nat. Phys. 6, 249 (2010).
[32] F. Dolde, I. Jakobi, B. Naydenov, N. Zhao, S. Pezzagna, C. Trautmann, J. Meijer, P. Neumann, F. Jelezko, and J. Wrachtrup, Nat. Phys. 9, 139 (2013).
[33] E. L. Rosenfeld, L. M. Pham, M. D. Lukin, and R. L. Walsworth, Phys. Rev. Lett. 120, 243604 (2018).
[34] A. Cooper, W. K. C. Sun, J. C. Jaskula, and P. Cappellaro, Phys. Rev. Lett. 124, 083602 (2020).
[35] J. Lee, M. Tatsuta, A. Xu, E. Bauch, M. J. H. Ku, and R. L. Walsworth, arXiv: 2203.07610 (2022).
[36] T. Yamamoto et al., Phys. Rev. B 88, 075206 (2013).
[37] H. Okushi, H. Watanabe, S. Ri, S. Yamanaka, and D. Takeuchi, J. Cryst. Growth 237-239, 1269 (2002).
[38] K. Ohno, Ph.D. thesis, University of California, Santa Barbara (2014).
[39] T. R. Eichhorn, C. A. Mclellan, and A. C. B. Jayich, Phys. Rev. Mater. 3, 113802 (2019).
[40] P. Balasubramanian, C. Osterkamp, O. Brinza, M. Rollo, I. Robert-Philip, P. Goldner, V. Jacques, F. Jelezko, J. Achard, and A. Tallaire, Carbon 194, 282 (2022).
[41] K. Ohno, F. J. Heremans, L. C. Bassett, B. A. Myers, D. M. Toyli, A. C. B. Jayich, C. J. Palmstrøm, and D. D. Awschalom, Appl. Phys. Lett. 101, 082413 (2012).
[42] K. Ohno, F. J. Heremans, C. F. D. L. Casas, B. A. Myers, B. J. Alemán, A. C. B. Jayich, and D. D. Awschalom, Appl. Phys. Lett. 105, 052406 (2014).
[43] C. A. Mclellan, B. A. Myers, S. Kraemer, K. Ohno, D. D. Awschalom, and A. C. B. Jayich, Nano Lett. 16, 2450 (2016).
[44] D. M. Toyli, C. D. Weis, G. D. Fuchs, T. Schenkel, and D. D. Awschalom, Nano Lett. 10, 3168 (2010).
[45] P. Spinicelli et al., New J. Phys. 13, 025014 (2011).
[46] S. Sangtawesin, T. O. Brundage, Z. J. Atkins, and J. R. Petta, Appl. Phys. Lett. 105, 063107 (2014).
[47] I. Jakobi et al., J. Phys: Conf. Ser. 752, 012001 (2016).
[48] I. Bayn et al., Nano Lett. 15, 1751 (2015).
[48] T.-Y. Hwang, J. Lee, S.-W. Jeon, Y.-S. Kim, Y.-W. Cho, H.-T. Lim, S. Moon, S.-W. Han, Y.-H. Choa, and H. Jung, Nano Lett. 22, 1672 (2022).
[50] N. Mizuochi et al., Phys. Rev. B 80, 041201(R) (2009).
[51] G. Balasubramanian et al., Nat. Mater. 8, 383 (2009).
[52] E. J. Davis et al., Nat. Phys. 10.1038/s41567-023-01944-5 (2023).
[53] L. B. Hughes et al., APL Mater. 11, 021101 (2023).
[54] T. Lühmann, R. John, R. Wunderlich, J. Meijer, and S. Pezzagna, Nat. Commun. 10, 4956 (2019).
[55] E. D. Herbschleb et al., Nat. Commun. 10, 3766 (2019).
[56] R. Kawase, H. Kawashima, H. Kato, N. Tokuda, S. Yamasaki, M. Ogura, T. Makino, and N. Mizuochi, arXiv: 2205.15539 (2022).
[57] E. Bauch et al., Phys. Rev. B 102, 134210 (2020).
[58] H. Park, J. Lee, S. Han, S. Oh, and H. Seo, npj Quantum Inf. 8, 95 (2022).
[59] M. Onizhuk and G. Galli, Appl. Phys. Lett. 118, 154003 (2021).
[60] M. Onizhuk and G. Galli, Adv. Theory Simul. 4, 2100254 (2021).
[61] S. Kanai, F. J. Heremans, H. Seo, G. Wolfowicz, C. P. Anderson, S. E. Sullivan, M. Onizhuk, G. Galli, D. D. Awschalom, and H. Ohno, Proc. Natl. Acad. Sci. U.S.A. 119, e2121808119 (2022).
[62] S. L. Bayliss, P. Deb, D. W. Laorenza, M. Onizhuk, G. Galli, D. E. Freedman, and D. D. Awschalom, Phys. Rev. X 12, 031028 (2022).
[63] N. P. de Leon, K. M. Itoh, D. Kim, K. K. Mehta, T. E. Northup, H. Paik, B. S. Palmer, N. Samarth, S. Sangtawesin, and D. W. Steuerman, Science 372, eabb2823 (2021).
[64] C. Shinei, Y. Masuyama, M. Miyakawa, H. Abe, S. Ishii, S. Saiki, S. Onoda, T. Taniguchi, T. Ohshima, and T. Teraji, J. Appl. Phys. 132, 214402 (2022).
[65] U. Zvi et al., arXiv: 2305.03075 (2023).
[66] W. Yang and R.-B. Liu, Phys. Rev. B 78, 085315 (2008).
[67] W. Yang and R.-B. Liu, Phys. Rev. B 79, 115320 (2009).
[68] M. Annis, W. Cheston, and H. Primakoff, Rev. Mod. Phys. 25, 818 (1953).
[69] A. Cox, M. E. Newton, and J. M. Baker, J. Phys.: Condens. Matter 6, 551 (1994).
[70] M. Onizhuk, K. C. Miao, J. P. Blanton, H. Ma, C. P. Anderson, A. Bourassa, D. D. Awschalom, and G. Galli, PRX Quantum 2, 010311 (2021).
[71] N. Zhao, S. W. Ho, and R. B. Liu, Phys. Rev. B 85, 115303 (2012).
[72] X. Guo, N. Delegan, J. C. Karsch, Z. Li, T. Liu, R. Shreiner, A. Butcher, D. D. Awschalom, F. J. Heremans, and A. A. Clerk, Nano Lett. 21, 10392 (2021).
[73] A. Tallaire, M. Kasu, K. Ueda, and T. Makimoto, Diam. Relat. Mater. 17, 60 (2008).
[74] D. A. Broadway et al., Nat. Electron. 1, 502 (2018).
[75] J. N. Neethirajan et al., Nano Lett. 10.1021/acs.nanolett.2c04733 (2023).

1. A method, comprising:
receiving, for each of a plurality of spin qubits embedded within a spin bath, a respective one of a plurality of measured coherence times, the plurality of spin qubits and spin bath forming a solid-state sample;
determining, for each coherence time of the plurality of measured coherence times and each spin-bath configuration of a plurality of spin-bath configurations, a respective one of a plurality of partial probability densities, each of the plurality of partial probability densities being derived from a coherence model and identifying a probability density of measuring said each coherence time for said each spin-bath configuration, the plurality of spin-bath configurations spanning first and second spin-bath parameters;
determining, based on the plurality of partial probability densities for each spin-bath configuration, a respective one of a plurality of total probability densities, each of the plurality of total probability densities being a probability density of measuring all of the plurality of measured coherence times for said each spin-bath configuration;
determining, based on one or more growth parameters used to grow the solid-state sample, a value of the first spin-bath parameter for the spin bath of the solid-state sample;
determining, based on a subset of the plurality of total probability densities that are consistent with the value of the first spin-bath parameter, a value of the second spin-bath parameter for the spin bath of the solid-state sample; and
outputting the value of the second spin-bath parameter.

2. The method of claim 1, further comprising identifying, based on the value of the second spin-bath parameter, one or more subsequent growth parameters.

3. The method of claim 2, further comprising synthesizing an additional solid-state sample based on the one or more subsequent growth parameters.

4-7. (canceled)

8. The method of claim 1, each of the plurality of qubits comprising a nitrogen-vacancy center in diamond.

9. (canceled)

10. The method of claim 1, wherein:
the first spin-bath parameter is a thickness of the spin bath; and
the second spin-bath parameter is a density of a species of point defect forming the spin bath.

11-13. (canceled)

14. The method of claim 1, wherein each of the plurality of measured coherence times is a respective one of a plurality of inhomogeneous relaxation times.

15. The method of claim 14, further comprising performing Ramsey interferometry on each of the plurality of spin qubits to obtain a respective one of the plurality of inhomogeneous relaxation times.

16. The method of claim 1, wherein each of the plurality of measured coherence times is a respective one of a plurality of homogeneous relaxation times.

17. The method of claim 16, further comprising measuring each of the plurality of spin qubits to obtain a respective one of the plurality of homogeneous relaxation times.

18-20. (canceled)

21. The method of claim 1, wherein said outputting the value of the second spin-bath parameter comprises using the value of the second spin-bath parameter to design or calibrate a quantum device using the solid-state sample.

22-26. (canceled)

27. A system, comprising:
a processor; and
a memory in electronic communication with the processor, the memory storing machine-readable instructions that, when executed by the processor, control the system to:
receive, for each of a plurality of spin qubits embedded within a spin bath, a respective one of a plurality of measured coherence times, the plurality of spin qubits and spin bath forming a solid-state sample,
determine, for each coherence time of the plurality of measured coherence times and each spin-bath configuration of a plurality of spin-bath configurations, a respective one of a plurality of partial probability densities, each of the plurality of partial probability densities being derived from a coherence model and identifying a probability density of measuring said each coherence time for said each spin-bath configuration, the plurality of spin-bath configurations spanning first and second spin-bath parameters,
determine, based on the plurality of partial probability densities for each spin-bath configuration, a respective one of a plurality of total probability densities, each of the plurality of total probability densities being a probability density of measuring all of the plurality of measured coherence times for said each spin-bath configuration,
determine, based on one or more growth parameters used to grow the solid-state sample, a value of the first spin-bath parameter for the spin bath of the solid-state sample,
determine, based on a subset of the plurality of total probability densities that are consistent with the value of the first spin-bath parameter, a value of the second spin-bath parameter for the spin bath of the solid-state sample, and
output the value of the second spin-bath parameter.

28. The system of claim 27, the memory storing additional machine-readable instructions that, when executed by the processor, control the system to identify, based on the value of the second spin-bath parameter, one or more subsequent growth parameters.

29. The system of claim 28, further comprising a chemical vapor deposition system configured to grow an additional solid-state sample based on the one or more subsequent growth parameters.

30-33. (canceled)

34. The system of claim 27, each of the plurality of qubits comprising a nitrogen-vacancy center in diamond.

35. (canceled)

36. The system of claim 27, wherein:
the first spin-bath parameter is a thickness of the spin bath; and
the second spin-bath parameter is a density of a species of point defect forming the spin bath.

37-39. (canceled)

40. The system of claim 27, wherein each of the plurality of measured coherence times is a respective one of a plurality of inhomogeneous relaxation times.

41. The system of claim 40, further comprising a Ramsey interferometer configured to perform Ramsey interferometry on each of the plurality of spin qubits to obtain a respective one of the plurality of inhomogeneous relaxation times.

42. The system of claim 27, wherein each of the plurality of measured coherence times is a respective one of a plurality of homogeneous relaxation times.

43. The system of claim 42, further comprising a spectrometer configured to measure each of the plurality of spin qubits to obtain a respective one of the plurality of homogeneous relaxation times.

44-46. (canceled)

47. The system of claim 27, further comprising a quantum device that uses the solid-state sample.

48-51. (canceled)
